(19) United States
(12) Patent Application Publication
(10) Pub. No.: US 2026/0262549 A1
(43) Pub. Date: Sep. 3, 2026

(54) SEMICONDUCTOR MODULE MANUFACTURING METHOD AND SEMICONDUCTOR MODULE

(71) Applicant: Premo, Inc., Tokyo (JP)

(72) Inventors: Kenichi FUJIKAWA, Osaka (JP); Hidenori TSUJI, Tokyo (JP)

(21) Appl. No.: 19/165,090

(22) PCT Filed: Feb. 1, 2024
(86) PCT No.: PCT/JP2024/003325

§ 371 Date: Sep. 12, 2025

(30) Foreign Application Priority Data
Mar. 29, 2023 (JP) 2023-052610

(51) Int. Cl. H10W 90/10; H10D 1/20; H10D 80/20

(52) U.S. Cl. CPC H10W 90/10; H10D 1/20; H10D 80/211

(57) ABSTRACT

A semiconductor module comprising: a first semiconductor chip having a first coil; a second semiconductor chip having a second coil capable of communication with the first coil via inductive coupling, the second semiconductor chip being disposed spaced apart in a horizontal direction perpendicular to an axial direction of the first coil; and a magnetic material disposed on a closed magnetic circuit relating to the inductive coupling at least between the first and second semiconductor chips.

### RELATED APPLICATIONS

The present application is a National Phase of International Application No. PCT/JP2024/003325 filed Feb. 1, 2024, which claims priority to Japanese Application No. 2023-052610, filed Mar. 29, 2023.

### TECHNICAL FIELD

The present invention relates to a semiconductor module manufacturing method and a semiconductor module.

### BACKGROUND ART

Conventionally, in semiconductor chip modules that integrate a plurality of semiconductor chips within one package, wired signal transmission using wire bonding, silicon interposers, or the like has been performed for signal transmission between the plurality of integrated semiconductor chips. Such semiconductor chip modules that perform wired signal transmission have a problem that manufacturing is not easy because thousands of communication lines need to be connected between the semiconductor chips and the substrate, and the semiconductor chips need to be bonded to predetermined positions on the substrate with high accuracy. PTL 1 proposes a technology for reducing the number of communication lines between semiconductor chips and the substrate by utilizing wireless communication using coils instead of wired communication lines to address the above-described problem.

However, even when signal transmission between a plurality of semiconductor chips is performed by wireless communication and communication lines are not used, in order to make the plurality of semiconductor chips function, it is necessary to connect the substrate and the semiconductor chips with wired power lines to supply power to each semiconductor chip. Therefore, it is necessary to bond the semiconductor chips to predetermined positions on the substrate where power can be supplied, and as in the conventional case, it is necessary to bond the semiconductor chips to predetermined positions on the substrate with high accuracy, leaving the problem that manufacturing is not easy.

### CITATION LIST

### Patent Literature

[PTL 1] Japanese Patent Application Laid-Open No. 2021-87044

### SUMMARY OF INVENTION

### Technical Problem

However, the information processing apparatus described in PTL 1 did not consider an implementation method of power supply lines to semiconductor chips for enabling easier manufacturing.

The present invention has been made in view of such background, and aims to provide a semiconductor module and a semiconductor module manufacturing method that can be manufactured more easily.

### Solution to Problem

One aspect of the present invention for solving the above problem is a semiconductor module comprising: a first semiconductor chip having a first coil; a second semiconductor chip having a second coil capable of communication with the first coil via inductive coupling, the second semiconductor chip being disposed spaced apart in a horizontal direction perpendicular to an axial direction of the first coil; and a magnetic material disposed on a closed magnetic circuit relating to the inductive coupling at least between the first and second semiconductor chips.

Other problems disclosed by the present application and methods for solving them will be clarified by the embodiments section and the drawings.

### Advantageous Effects of Invention

According to the present invention, semiconductor chips and semiconductor chip modules can be manufactured more easily.

### BRIEF DESCRIPTION OF DRAWINGS

FIG. 1 A diagram showing a hardware configuration example of a semiconductor chip according to an embodiment of the present invention.

FIG. 2 A configuration diagram applying a coil 70 as an example of implementing a sensing unit 30 and a communication unit 40 according to an embodiment of the present invention.

FIG. 3 A block diagram showing a functional configuration of a semiconductor chip according to an embodiment of the present invention.

FIG. 4 A control flow diagram explaining a processing flow according to an embodiment of the present invention.

FIG. 5a and FIG. 5b Diagrams showing a first implementation example of mounting a semiconductor chip on a substrate according to an embodiment of the present invention.

FIG. 6 A configuration diagram of a semiconductor chip when supplying multiple levels of voltage to the semiconductor chip according to an embodiment of the present invention.

FIG. 7 A diagram showing a first implementation example when supplying multiple levels of voltage to a semiconductor chip according to an embodiment of the present invention.

FIG. 8 A diagram showing a third implementation example of mounting a semiconductor chip on a substrate according to an embodiment of the present invention.

FIG. 9 A diagram showing a fourth implementation example of mounting a semiconductor chip on a substrate according to an embodiment of the present invention.

FIG. 10a to FIG. 10c Diagrams showing a fifth implementation example of mounting a semiconductor chip on a substrate according to an embodiment of the present invention.

FIG. 11a and FIG. 11b Diagrams showing a sixth implementation example of mounting a semiconductor chip on a substrate according to an embodiment of the present invention.

FIG. 12 A diagram showing a seventh implementation example of mounting a semiconductor chip on a substrate according to an embodiment of the present invention.

FIG. 13 A diagram showing an eighth implementation example of mounting a semiconductor chip on a substrate according to an embodiment of the present invention.

FIG. 14 A flowchart showing a manufacturing process of a semiconductor chip module according to an embodiment of the present invention.

FIG. 15 A diagram explaining a manufacturing method of a semiconductor module by an RtR method according to an embodiment of the present invention.

FIG. 16 A diagram explaining a manufacturing method of a semiconductor module by an RtR method when providing a bending process according to an embodiment of the present invention.

FIG. 17 A diagram explaining a process of bending tape in a semiconductor module manufacturing method according to an embodiment of the present invention.

FIG. 18 A diagram explaining a folded structure of a semiconductor module according to an embodiment of the present invention.

FIG. 19 A diagram explaining another folded structure of a semiconductor module according to an embodiment of the present invention.

FIG. 20 A diagram showing an arrangement example of magnetic materials.

FIG. 21 A diagram showing an arrangement example of sheet-shaped magnetic materials.

FIG. 22 A diagram showing an example of disposing a magnetic material sheet 911 on the back surface of a substrate 100.

FIG. 23 A diagram showing a case where the substrate 100 is used as a magnetic sheet 911.

FIG. 24 A diagram showing an example of disposing a magnetic material 902 in a gap between semiconductor chips 1a and 1b.

FIG. 25 A diagram showing an implementation example of semiconductor chips 1a and 1b.

FIG. 26 A diagram showing an example of spacing semiconductor chips 1a and 1b apart in a vertical direction.

FIG. 27 A diagram showing an example of stacking semiconductor chips 1a and 1b by bending processing.

FIG. 28 A diagram showing another example of stacking semiconductor chips 1a and 1b by bending processing.

FIG. 29 A diagram explaining a method of manufacturing a semiconductor module together with a magnetic material sheet 911 by a continuous conveying method.

FIG. 30 A diagram explaining another example of manufacturing a semiconductor module together with magnetic materials by a continuous conveying method.

FIG. 31 A diagram explaining a semiconductor module in which semiconductor chips 1a and 1b are stacked spaced apart in a vertical direction.

FIG. 32 A diagram showing an example of disposing a magnetic material between coils.

FIG. 33 A diagram showing an example of disposing a plurality of magnetic materials.

FIG. 34 A diagram showing an example of forming a semiconductor module by bending processing.

FIG. 35 A diagram showing an example of disposing a magnetic material sheet 911.

### DESCRIPTION OF EMBODIMENTS

### Overview of Invention

The contents of embodiments of the present invention are listed and described. The present invention comprises, for example, the following configurations.

### [Item 1]

A semiconductor module comprising:
a first semiconductor chip having a first coil;
a second semiconductor chip having a second coil capable of communication with the first coil via inductive coupling, the second semiconductor chip being disposed spaced apart in a horizontal direction perpendicular to an axial direction of the first coil; and
a magnetic material disposed on a closed magnetic circuit relating to the inductive coupling at least between the first and second semiconductor chips.

### [Item 2]

The semiconductor module according to item 1, wherein
the first and second semiconductor chips are disposed on a substrate formed by the magnetic material.

### [Item 3]

The semiconductor module according to item 1, wherein
a sheet-shaped magnetic material is provided on one surface of a substrate on which the first and second semiconductor chips are disposed.

### [Item 4]

The semiconductor module according to item 3, wherein
the magnetic material is fixed to the one surface of the substrate by lamination processing.

### [Item 5]

The semiconductor module according to item 1, wherein
the magnetic material is disposed in a gap between the first and second semiconductor chips on one surface of a substrate on which the first and second semiconductor chips are disposed.

### [Item 6]

The semiconductor module according to item 1, wherein
the first and second semiconductor chips are mounted on a substrate,
the substrate comprises a positive electrode power supply area having an exposed positive electrode and a negative electrode power supply area having an exposed negative electrode,
the first and second semiconductor chips each comprise a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.

### [Item 7]

A semiconductor module comprising:
a first semiconductor chip having a first coil;
a second semiconductor chip having a second coil capable of communication with the first coil via inductive coupling, the second semiconductor chip being disposed spaced apart in an axial direction of the first coil;
opposing surfaces of the first and second semiconductor chips; respective opposite surfaces spaced apart from the opposing surfaces in the axial direction; and
a magnetic material disposed in proximity to at least one of the respective opposite surfaces.

### [Item 8]

The semiconductor module according to item 7, wherein
the first and second semiconductor chips are mounted on a first surface of a same substrate,
a sheet-shaped magnetic material is disposed on the first surface of the substrate or on a second surface opposite to the first surface, and the substrate is folded so that the first and second semiconductor chips face each other.

### [Item 9]

The semiconductor module according to item 8, wherein
the magnetic material is fixed to the substrate by lamination processing.

### [Item 10]

The semiconductor module according to item 8, wherein
the semiconductor chips are fixed to the substrate by lamination processing.

### [Item 11]

The semiconductor module according to item 7, wherein
the first and second semiconductor chips are mounted on a substrate,
the substrate comprises a positive electrode power supply area having an exposed positive electrode and a negative electrode power supply area having an exposed negative electrode,
the first semiconductor chip comprises a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.

### [Item 12]

A semiconductor module comprising:
a first semiconductor chip having a first coil;
a second semiconductor chip having a second coil capable of communication with the first coil via inductive coupling, the second semiconductor chip being disposed spaced apart in an axial direction of the first coil; and
a magnetic material disposed on a closed magnetic circuit relating to the inductive coupling between the first and second semiconductor chips.

### [Item 13]

The semiconductor module according to item 12, wherein
the magnetic material is disposed between opposing surfaces of the first and second semiconductor chips.

### [Item 14]

The semiconductor module according to item 12, wherein
a plurality of magnetic materials are disposed.

### [Item 15]

The semiconductor module according to item 12, wherein
the magnetic material is fixed to the first or second semiconductor chip by lamination processing.

### [Item 16]

The semiconductor module according to item 12, wherein
the first and second semiconductor chips are mounted on a first surface of a same substrate, and
the substrate is folded so that the first and second semiconductor chips face each other.

### [Item 17]

The semiconductor module according to item 16, wherein
a sheet-shaped magnetic material is disposed on the first surface of the substrate or on a second surface opposite to the first surface.

### [Item 18]

The semiconductor module according to item 17, wherein
the magnetic material is fixed to the substrate by lamination processing.

### [Item 19]

The semiconductor module according to item 12, wherein
the first and second semiconductor chips are mounted on a substrate,
the substrate comprises a positive electrode power supply area having an exposed positive electrode and a negative electrode power supply area having an exposed negative electrode,
the first and second semiconductor chips each comprise a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.

### Hardware

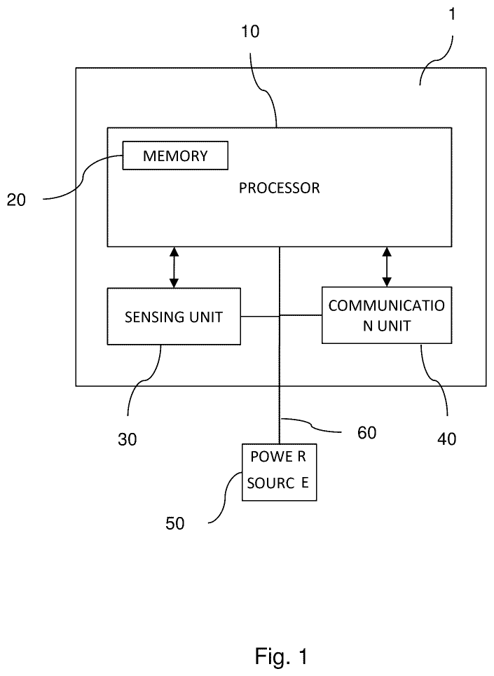

FIG. 1 shows a hardware configuration example of a semiconductor chip according to an embodiment of the present invention. The semiconductor chip 1 comprises a processor 10, a sensing unit 30, and a communication unit 40, and the processor 10 comprises a memory 20. The sensing unit 30 measures measurement values according to the environment in which the semiconductor chip is deployed. The processor 10 receives the measurement values measured by the sensing unit 30, records them in the memory 20, and calculates environmental values by providing the measurement values to calculation logic. The environmental values are values indicating the state of the environment in which the semiconductor chip is deployed. The processor 10 records the calculated environmental values in the memory 20. Further, the semiconductor chip 1 has a power line 60 and supplies power from an external power source 50 to the processor 10, the sensing unit 30, and the communication unit 40.

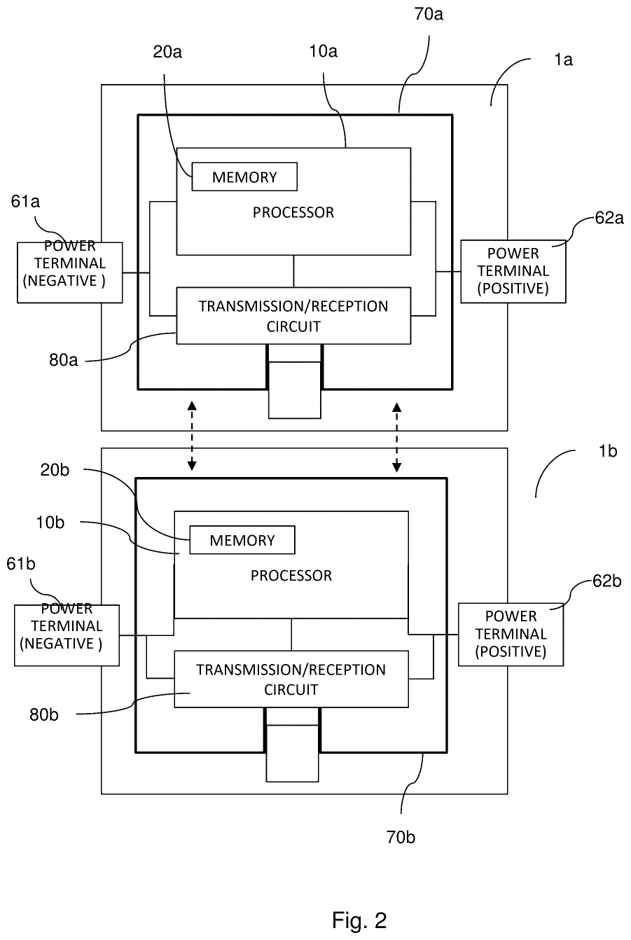

FIG. 2 shows a hardware configuration example applying a coil 70 as an example of implementing the sensing unit 30 and the communication unit 40. The example shown in FIG. 2 shows an example using semiconductor chips in pairs, and the semiconductor chips comprise processors (10a, 10b), memories (20a, 20b) provided in the processors, transmission/reception circuits (80a, 80b) communicatively connected to the processors, coils (70a, 70b) connected to the transmission/reception circuits, first power terminals (61a, 61b) on the negative electrode side for supplying power to the processors and the transmission/reception circuits, and second power terminals (62a, 62b) on the positive electrode side.

The two adjacently disposed semiconductor chips (1a, 1b) shown in FIG. 2 each comprise coils (70a, 70b) and transmission/reception circuits (80a, 80b) that generate signals flowing through the coils, thereby being able to transmit and receive signals to and from each other via inductive coupling with the coils 70 of the other adjacent semiconductor chips. Further, when the relative distance or relative angle between the coils (70a, 70b) of the two semiconductor chips changes, the coupling strength of the inductive coupling changes, and the voltage value or voltage amplitude value generated in the coils changes. In this embodiment, by the transmission/reception circuits detecting the voltage value or voltage amplitude value generated in the coils, the processor 10 can acquire the detected voltage value or voltage amplitude value as measurement values and calculate environmental changes that change the relative distance or relative angle between the semiconductor chips as environmental values. The memory 20 records the calculated environmental values.

The semiconductor chip of this embodiment stores calculation logic for each of a plurality of types of environmental values and can calculate multiple types of environmental values from the same measurement values. By using calculation logic corresponding to a specified type, the semiconductor chip can obtain different types of environmental values based on measurement values from the same sensor (voltage measured by the coil 70). Further, by implementing the processor, sensing unit, and communication unit shown in FIG. 1 inseparably on the semiconductor chip, the semiconductor chip in this embodiment can be configured with a CPU. In that case, the diameter of the semiconductor chip can be, for example, about 0.3 mm, and the semiconductor chip can be miniaturized. Note that it is not limited to this size. For example, the processor, sensing unit, and communication unit can be implemented inseparably on a semiconductor chip (on one chip). Here, a semiconductor chip is defined as a small thin piece of silicon (silicon die, or die) incorporating electronic circuits.

Alternatively, in some cases, it can also be defined as a package enclosing a silicon die.

### Software

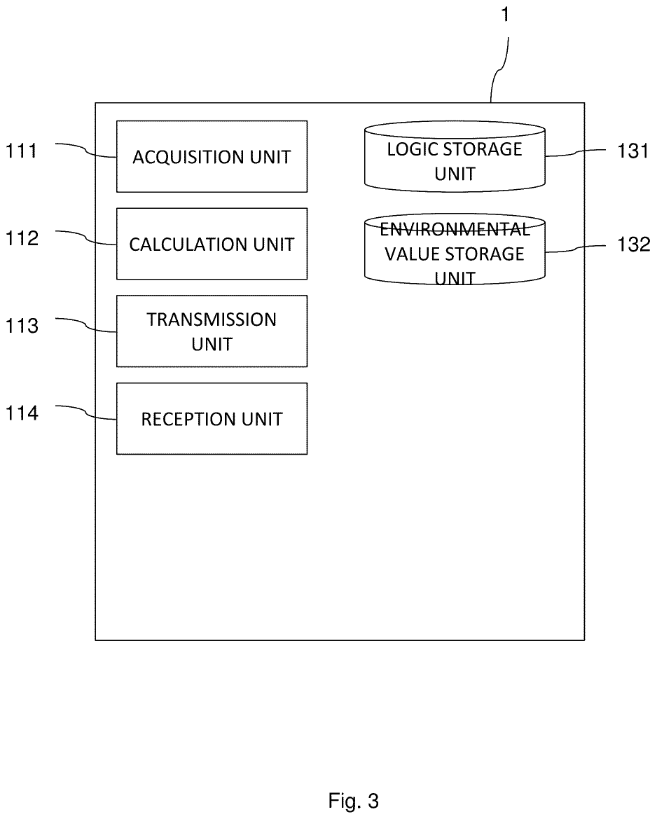

FIG. 3 is a block diagram showing the functional configuration of a semiconductor chip. As shown in FIG. 3, the semiconductor chip comprises an acquisition unit 111, a calculation unit 112, a transmission unit 113, a reception unit 114, a logic storage unit 131, and an environmental value storage unit 132.

The logic storage unit 131 stores calculation logic. The logic storage unit 131 of this embodiment stores calculation logic for each type of environmental value. The logic storage unit 131 stores calculation logic in association with types of environmental values. As described above, the calculation logic includes algorithms for calculating environmental values based on measurement values. The measurement values are voltage values or voltage amplitude values generated in coils detected by the transmission/reception circuits, and in this embodiment can be, for example, voltage values generated in coils. The environmental values are values related to the environment in which the sensor chips are placed and can be, for example, temperature, vibration, pressure, electromagnetic waves, sound volume, humidity, etc. For example, when the positional relationship between two sensor chips changes, the voltage or voltage amplitude generated in the coils changes. Further, it is known that changes in the positional relationship of two sensor chips change due to temperature, pressure, humidity, etc. around the sensor chips, vibrations such as sound or electromagnetic waves applied from outside the sensor chips, vibrations of objects in which the sensor chips are embedded, disposed, or attached, etc., and by processing the voltage changes or voltage changes in coils that occur due to changes in the relative positional relationship of the sensor chips with appropriate calculation logic, it is possible to calculate, for example, temperature, vibration, pressure, electromagnetic waves, sound volume, humidity, etc.

The environmental value storage unit 132 stores environmental values. The environmental value storage unit 132 of this embodiment stores histories of environmental values for each type. The environmental value storage unit 132 includes information such as the type of environmental value, environmental value, calculation time point (timestamp), etc., but is not limited to these. The timestamp may be the time point when the measurement values were measured.

The condition storage unit 133 stores information for determining which type of environmental values to calculate. The condition storage unit 133 of this embodiment stores types of environmental values to be calculated when the conditions are satisfied, in association with conditions for events that the semiconductor chip can acquire. Multiple pairs of conditions and types of environmental values may be registered. Note that the condition storage unit 133 may store types of environmental values to be calculated unconditionally. Further, the condition storage unit 133 may store one or more types of environmental values to be calculated without providing conditions.

The acquisition unit 111 acquires measurement values measured by the sensing unit (coil) provided in the semiconductor chip. The acquisition unit 111 of this embodiment can acquire voltage values generated in the coil 30 as measurement values.

The calculation unit 112 calculates environmental values. The calculation unit 112 can calculate environmental values from measurement values using calculation logic corresponding to set types. The calculation unit 112 can, for example, identify types corresponding to conditions that are satisfied among conditions stored in the condition storage unit 133, read calculation logic corresponding to the identified types from the logic storage unit 131, provide measurement values acquired by the acquisition unit 111 to the read calculation logic, and calculate environmental values.

Further, the calculation unit 112 can calculate first type environmental values from measurement values acquired from the coil 30 using first calculation logic, and can also calculate second type environmental values using second calculation logic different from the first calculation logic. For example, the calculation unit 112 can provide measurement values to calculation logic corresponding to temperature and also provide them to calculation logic corresponding to humidity to calculate temperature and humidity.

Further, the calculation unit 112 can calculate corresponding environmental values according to measurement logic that matches conditions. The calculation unit 112 can, for example, determine whether time information acquirable from a clock (not shown) and measurement values acquired from the coil 70 satisfy conditions stored in the condition storage unit 133, and when there are satisfied conditions, identify types corresponding to the satisfied conditions, read calculation logic corresponding to the identified types from the logic storage unit 131, and perform calculation of environmental values using the read calculation logic.

The reception unit 114 receives signals from outside the semiconductor chip. For example, it can receive identification information of the semiconductor chip (1b) and information on environmental values measured by the semiconductor chip (1b) from an adjacent semiconductor chip (1b). Further, it can receive environmental value request signals requesting output of environmental values stored in the environmental value storage unit.

### Operation

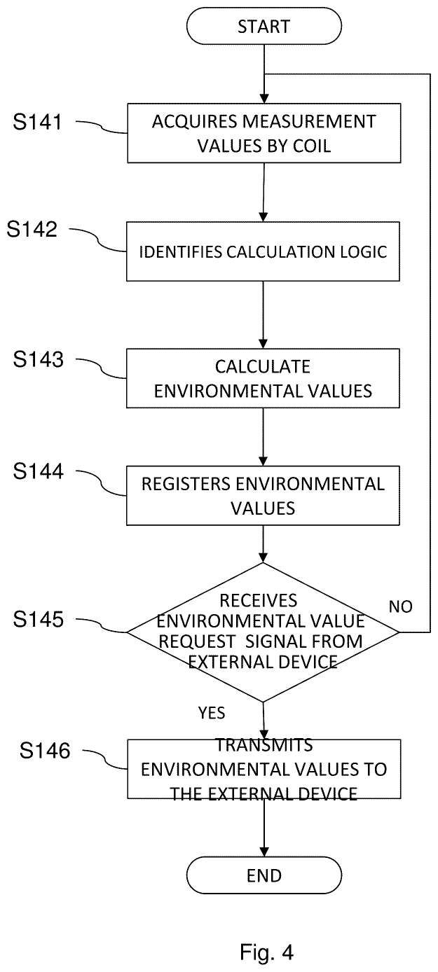

FIG. 4 is a control flow diagram explaining the flow of processing according to an embodiment of the present invention.

In the semiconductor chip, the acquisition unit 111 acquires measurement values (voltage of the coil 70 in this embodiment) measured by the sensor (S141). Next, the calculation unit 112 identifies types of environmental values corresponding to conditions that are fulfilled among conditions stored in the condition storage unit 133, identifies calculation logic corresponding to the identified types from the logic storage unit 131 (S142), provides measurement values to the identified calculation logic to calculate environmental values (S143), and registers the calculated environmental values in the environmental value storage unit 132 in association with the types of environmental values and timestamps (S144).

When the transmission unit 113 receives an environmental value request signal from an external device (S145: YES), it transmits environmental values registered in the environmental value storage unit 132 to the external device (S146). Here, the transmission unit 113 may transmit the latest environmental values, or may transmit histories of some or all environmental values.

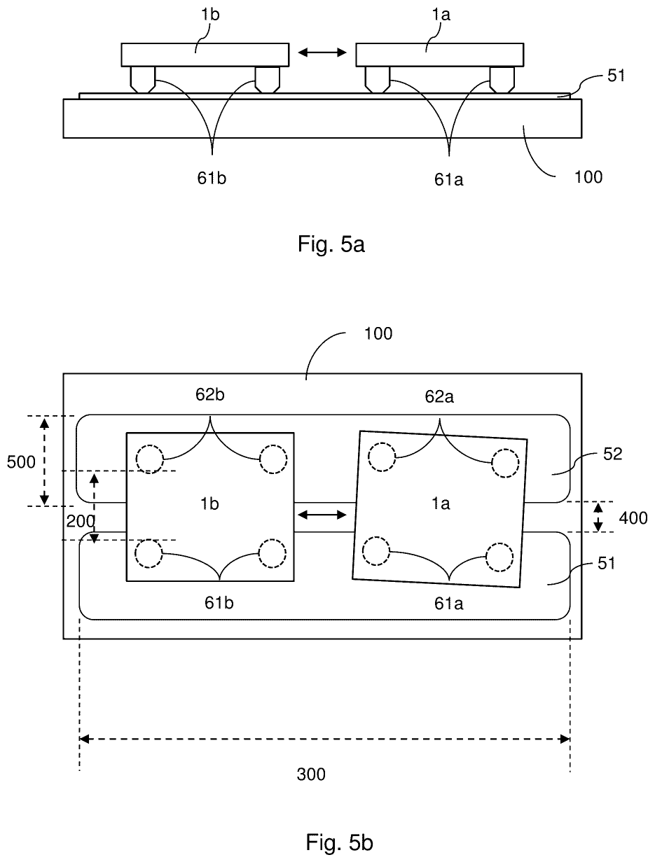

Hereinafter, specific examples of mounting the above-described semiconductor chip 1 on a substrate 100 will be described in FIGS. 5a to 8. In order to mount multiple semiconductor chips 1 on a substrate 100 and make each semiconductor chip 1 function, it is necessary to perform necessary communication between the semiconductor chips 1 and to supply power to each semiconductor chip 1. In each implementation example described below, specific examples of implementation structures that realize communication and power supply in multiple semiconductor chips 1 will be described.

### Implementation Example 1

FIG. 5a and FIG. 5b are diagrams showing a first implementation example of mounting the semiconductor chip 1 according to this embodiment on a substrate 100. FIG. 5a shows a side view, and FIG. 5b shows a plan view. As shown in FIG. 5a and FIG. 5b, a negative electrode side power supply area (51) and a positive electrode side power supply area (52) are provided on one side of the substrate 100. Further, a plurality of semiconductor chips (1a, 1b) are disposed on one side of the substrate 100, the negative electrode side power terminals (61) of the semiconductor chips are bonded to the negative electrode side power supply area (51), and the positive electrode side power terminals (62) of the semiconductor chips are bonded to the positive electrode side power supply area (52).

The semiconductor chip 1 can receive power supply from the substrate 100 via the negative electrode and positive electrode power terminals (61, 62), and can perform wireless communication with other semiconductor chips 1 via communication units configured with coils 70 and the like, so wiring connected between the substrate 100 and the semiconductor chip 1 becomes unnecessary except for power lines, and the wiring that conventionally numbered around several thousand lines can be significantly reduced. Therefore, the connection work between the substrate 100 and the semiconductor chip 1 is simplified, and it also becomes possible to use easily deformable materials as the substrate 100.

In the example shown in FIG. 5a and FIG. 5b, since each semiconductor chip 1 is provided with two negative electrode side power terminals (61) and two positive electrode side power terminals (62) respectively, for example, even when one of the two negative electrode side power terminals 61a of the semiconductor chip la becomes unable to contact the negative electrode side power supply area (51) due to defects in bonding work during manufacturing or due to deformation of the soft substrate 100, the semiconductor chip can obtain power via the other negative electrode side power terminal 61a. However, the power terminals do not necessarily need to be two, and may be three or more, or may be only one.

The power supply areas 51 and 52 provided on the substrate 100 are areas where positive electrode or negative electrode electrodes are exposed, and power terminals that contact the power supply areas 51 and 52 can obtain power supply via the power supply areas 51 and 52. The negative electrode side power supply area (51) and the positive electrode side power supply area (52) can be realized, for example, by conductive films or conductive plates provided on the surface of the substrate 100. Alternatively, when the substrate 100 has a laminated structure of conductors and non-conductors, they may be realized by the conductor layers. As shown in the plan view shown in FIG. 5b, the negative electrode side power supply area (51) and the positive electrode side power supply area (52) are provided at adjacent positions with a certain distance (400) between them so as not to contact each other. Here, the area of at least one of the positive electrode power supply area 52 and the negative electrode power supply area 51 is generated to be larger than the area of at least one terminal end of the positive electrode power terminal 62 and the negative electrode power terminal 61. With this configuration, in the manufacturing process of the semiconductor module, in the process of connecting the substrate 100 and the semiconductor chip 1, the connection between the power supply areas 51 and 52 and the power terminals 61 and 62 can be performed more easily even with poor positioning accuracy. Further, it is desirable that the distance (400) between the positive electrode power supply area 52 and the negative electrode power supply area 51 provided on the substrate 100 be shorter than the distance (200) between the positive electrode power terminal 62 and the negative electrode power terminal 61 of the semiconductor chips (1a, 1b). With this configuration, the degree of freedom in the arrangement position of the semiconductor chip 1 in the vertical direction in FIG. 5a and FIG. 5b are improved.

Further, the short side length (500) of each power supply area 51 and 52 is configured to be longer than the width of the power terminals (61, 62). With this configuration, in the process of connecting the substrate 100 and the semiconductor chip 1, the connection between the power supply areas 51 and 52 and the power terminals 61 and 62 can be performed without problems even with poor positioning accuracy in the short side direction of the power supply areas 51 and 52. For example, as shown in FIG. 5b, even when the orientation of the semiconductor chip la is rotated about 10 degrees relative to the substrate or other semiconductor chip 1b, it is connected to the substrate 100 by power lines and there is no interference with wireless communication with the semiconductor chip 1b, so the positioning difficulty of the semiconductor chip 1 during manufacturing becomes lower, and manufacturing costs can be reduced. In particular, when manufacturing a semiconductor module by connecting semiconductor chips 1 having a side length of 1 mm or 0.5 mm or less on the substrate 100, high positioning accuracy is generally required to align the positions of the power supply areas 51 and 52 and the power terminals 61 and 62, so manufacturing costs become very high. In such cases, by generating the area of at least one of the positive electrode power supply area 52 and the negative electrode power supply area 51 to be larger than the area of at least one terminal end of the positive electrode power terminal 62 and the negative electrode power terminal 61 as in the present invention, it becomes possible to manufacture a semiconductor module even with the low positioning accuracy described above. The present invention can be applied to all semiconductor modules regardless of the size of the semiconductor module, but when the present invention is applied to small semiconductor chips having a side length of 1 mm or 0.5 mm or less or semiconductor modules using them, the effects of the present invention become particularly large.

Here, when using semiconductor chips having a side length of 1 mm, as an example, the width of the terminal ends of the positive electrode and negative electrode power terminals can be set to about 0.1 mm to 0.3 mm, the distance (200) between the positive electrode power terminal 62 and the negative electrode power terminal 61 to about 0.3 to 0.7 mm, the distance (400) between the positive electrode power supply area 52 and the negative electrode power supply area 51 to about 0.1 to 0.6 mm, the vertical width (500) of the positive electrode power supply area 52 and the negative electrode power supply area 51 to 0.2 mm or more, and the horizontal width (300) of the positive electrode power supply area 52 and the negative electrode power supply area 51 (direction in which multiple chips are disposed) to 2.1 mm or more.

As intervals between multiple pins (terminals) of general semiconductor chips 1, full pitch of 1/10 inch (2.54 mm), half pitch of 1/20 inch (1.27 mm), and ¼ pitch of 1/40 inch (0.635 mm) are known, and furthermore, ⅛ pitch of 1/80 inch (0.3175 mm) is expected to be put into practical use. Therefore, at present, the distance (200) between the positive electrode power terminal and the negative electrode power terminal needs to be 0.3 mm or more, and including the widths of the positive electrode power terminal 62 and the negative electrode power terminal 61, the side length of the semiconductor chip 1 needs to be 0.5 mm or more. On the other hand, if the distance (400) between the positive electrode power supply area 52 and the negative electrode power supply area 51 is too short, the risk of short-circuiting increases, so the distance (400) between each area needs to be at least 0.1 mm or more. Further, in the semiconductor module manufacturing process, it is desirable to allow a positioning accuracy deviation of about 0.1 mm for the semiconductor chip 1.

Therefore, it is desirable to set the distance (400) between the positive electrode power supply area 52 and the negative electrode power supply area 51 to 0.1 mm or more and to a value shorter than the distance (200) between the positive electrode power terminal 62 and the negative electrode power terminal 61. The specific dimensions described above are merely examples of implementations applying the present invention, and the present invention is not limited to these specific dimensions.

### Implementation Example 2

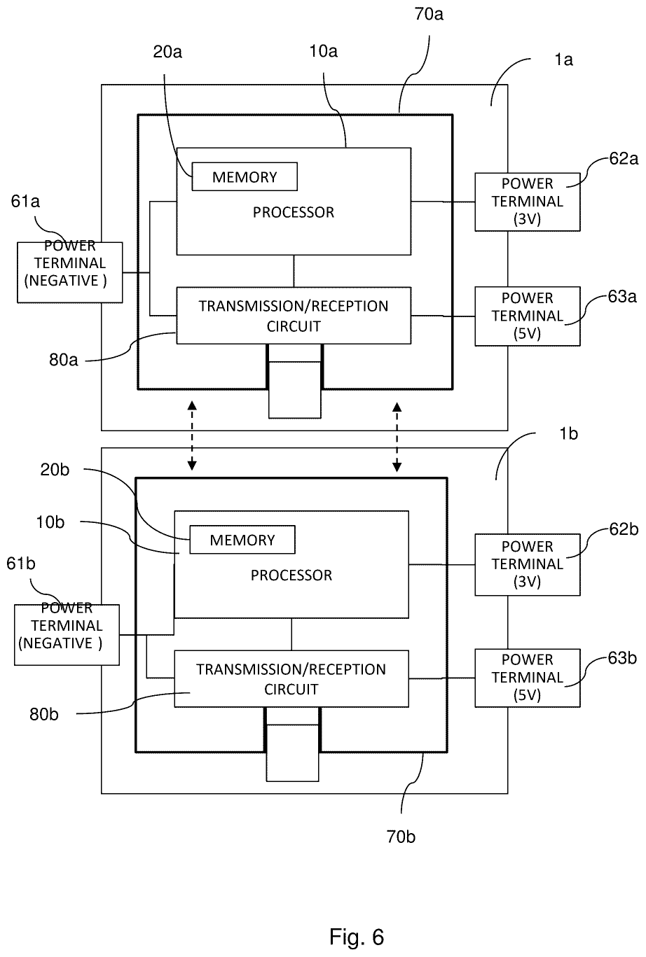

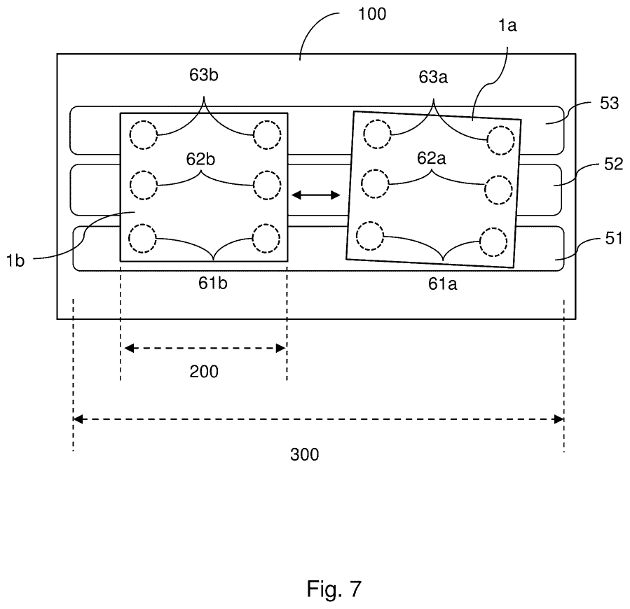

In FIGS. 6 and 7, an implementation example of supplying multiple levels of voltage to the semiconductor chip 1 will be described. FIG. 6 is a hardware configuration applying a coil 70 as an example of implementing the sensing unit 30 and the communication unit 40, and shows a configuration example different from FIG. 2. The example differs from the example shown in FIG. 2 in that the power terminals are configured with three types: a negative electrode power terminal 61, a first positive electrode power terminal (low voltage) 62, and a second positive electrode power terminal (high voltage) 63. The first positive electrode power terminal 62 is connected to a power source that supplies, for example, a 3V voltage, and the second positive electrode power terminal 63 is connected to a power source that supplies, for example, a 5V voltage, which is higher than the first positive electrode power terminal 62. The negative electrode power terminal 61 is a common power terminal connected to both the processor and the transmission/reception circuit, the first positive electrode power terminal 62 is connected to functional units requiring low voltage power (for example, the processor), and the second positive electrode power terminal 63 is connected to functional units requiring higher voltage power (for example, the transmission/reception circuit).

FIG. 7 is a diagram showing a second implementation example of mounting the semiconductor chip 1 according to this embodiment on a substrate 100. As shown in the plan view of FIG. 7, a negative electrode side power supply area (51), a positive electrode side first power supply area (52), and a positive electrode side second power supply area (53) are provided on one side of the substrate 100. Further, a plurality of semiconductor chips (1a, 1b) are disposed on one side of the substrate 100, the negative electrode side power terminals (61) of the semiconductor chips are bonded to the negative electrode side power supply area (51), the positive electrode side first power terminals (62) of the semiconductor chips are bonded to the positive electrode side first power supply area (52), and the positive electrode side second power terminals (63) of the semiconductor chips are bonded to the positive electrode side second power supply area (53). The positive electrode side first power supply area (52) is connected to a power source that supplies, for example, a 3V voltage, and the positive electrode side second power supply area (53) is connected to a power source that supplies, for example, a 5V voltage, which is higher than the first power supply area (52).

As in the implementation examples shown in FIGS. 6 and 7, even when the semiconductor chip 1 requires multiple levels of voltage, as shown in FIG. 7, by providing power supply areas (51, 52, 53) corresponding to each voltage on the substrate 100, the effect of lowering the positioning difficulty of the semiconductor chips during manufacturing and reducing manufacturing costs can be obtained.

### Implementation Example 3

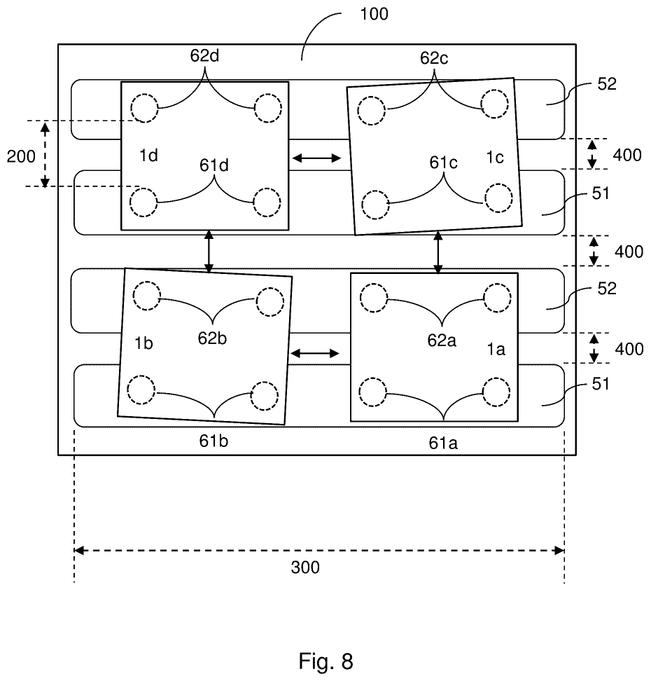

FIG. 8 is a diagram showing a third implementation example of mounting semiconductor chips according to this embodiment on a substrate 100. As shown in the plan view of FIG. 8, a negative electrode side power supply area (51) and a positive electrode side power supply area (52) are provided on one side of the substrate 100. Further, a plurality of semiconductor chips (1a, 1b) are disposed on one side of the substrate 100, the negative electrode side power terminals (61) of the semiconductor chips are bonded to the negative electrode side power supply area (51), and the positive electrode side power terminals (62) of the semiconductor chips are bonded to the positive electrode side power supply area (52). Here, unlike implementation example 1 shown in FIG. 5a and FIG. 5b, on one side of the substrate 100, the negative electrode side power supply area (51) and the positive electrode side power supply area (52) are alternately provided at a plurality of locations respectively. Therefore, by disposing semiconductor chips at arbitrary positions at the boundary between the negative electrode side power supply area (51) and the positive electrode side power supply area (52), it becomes possible to obtain power from the substrate 100, and the degree of freedom in arrangement when disposing the semiconductor chips 1 on the substrate 100 is improved.

### Implementation Example 4

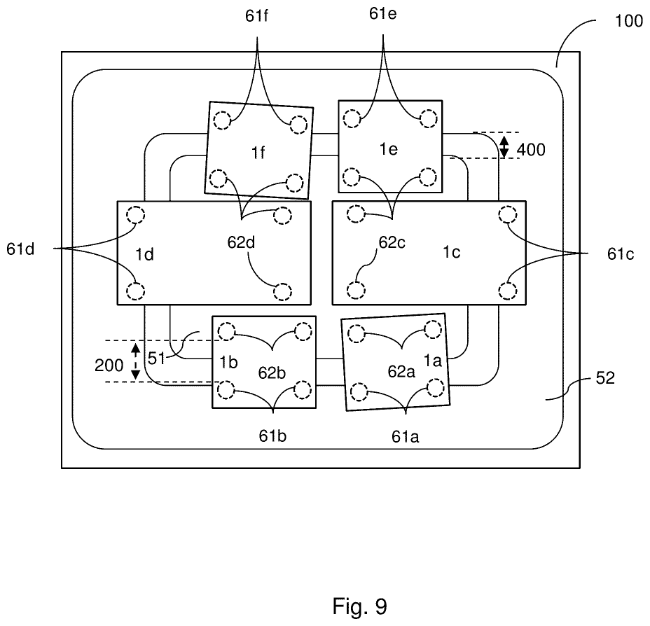

FIG. 9 is a diagram showing a fourth implementation example of mounting the semiconductor chip 1 according to this embodiment on a substrate 100. As shown in the plan view of FIG. 9, a negative electrode side power supply area (51) and a positive electrode side power supply area (52) are provided on one side of the substrate 100. Further, a plurality of semiconductor chips (1a, 1b, 1c, 1d, 1e, 1f) are disposed on one side of the substrate 100, the negative electrode side power terminals (61) of the semiconductor chips are bonded to the negative electrode side power supply area (51), and the positive electrode side power terminals (62) of the semiconductor chips are bonded to the positive electrode side power supply area (52). Here, unlike implementation example 3 shown in FIG. 8, on one side of the substrate 100, the negative electrode side power supply area (51) and the positive electrode side power supply area (52) are provided adjacently with one on the inside and the other surrounding the one, with a certain distance (400) between them so as not to contact each other. Therefore, by disposing the semiconductor chip 1 at arbitrary positions at the boundary between the negative electrode side power supply area (51) and the positive electrode side power supply area (52), it becomes possible to obtain power from the substrate 100, and the degree of freedom in arrangement when disposing the semiconductor chips 1 on the substrate 100 is improved.

### Implementation Example 5

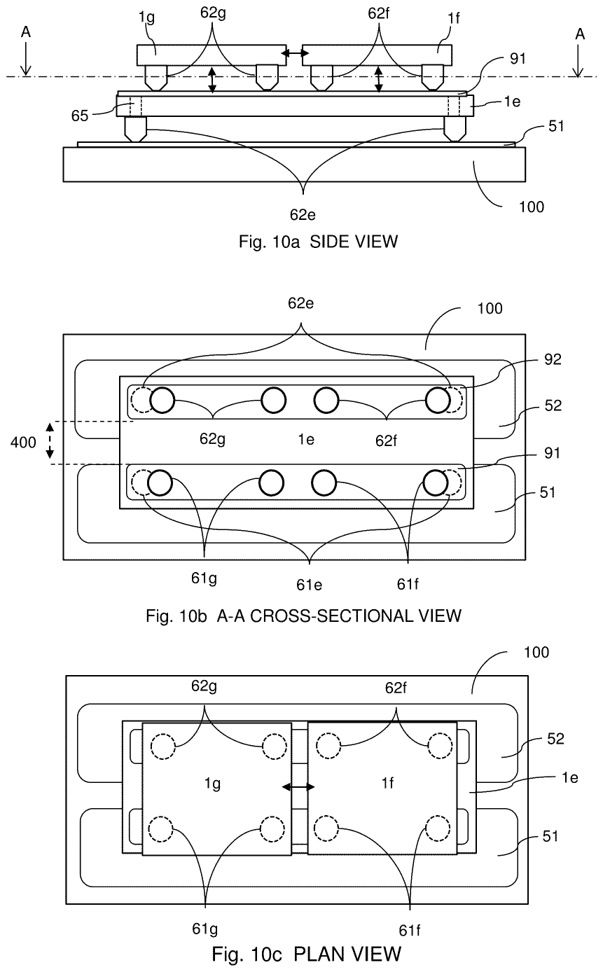

FIG. 10a to FIG. 10c are diagrams showing a fifth implementation example of mounting the semiconductor chip 1 according to this embodiment on a substrate 100. FIG. 10a shows a side view, FIG. 10b shows an A-A cross-sectional view, and FIG. 10c shows a plan view. As shown in FIG. 10a to FIG. 10c, a negative electrode side power supply area (51) and a positive electrode side power supply area (52) are provided on one side (upper side) of the substrate 100. Further, a semiconductor chip (le) is disposed on one side (upper side) of the substrate 100, the negative electrode side power terminal (61e) of the semiconductor chip (le) is bonded to the negative electrode side power supply area (51) of the substrate, and the positive electrode side power terminal (62e) of the semiconductor chip (le) is bonded to the positive electrode side power supply area (52) of the substrate 100. Here, unlike implementation examples 1-4 shown in FIGS. 5a-9, the semiconductor chip (le) that contacts the substrate 100 via the power supply areas is provided with a negative electrode area (91) having an exposed negative electrode side electrode and a positive electrode area (92) having an exposed positive electrode side electrode on the upper side of the chip, which is opposite to the lower side of the chip that has the power terminals (61e, 62e). The negative electrode area (91) and the positive electrode area (92) are provided adjacently with a certain distance (400) between them so as not to contact each other. The negative electrode area (91) of the semiconductor chip (1e) is electrically connected to the negative electrode power terminal (61e) via a negative electrode conductive part 65 provided inside the semiconductor chip (1e), and the positive electrode area (92) of the semiconductor chip (1e) is electrically connected to the power terminal (62e) via a positive electrode conductive part 65 provided inside the semiconductor chip (1e) and is connected to the power source of the substrate.

Further, semiconductor chips (1f, 1g) are further provided on the upper side of the semiconductor chip (1e), the negative electrode side power terminals (61f, 61g) of the semiconductor chips (1f, 1g) are bonded to the negative electrode area (91) of the semiconductor chip (1e), and the positive electrode side power terminals (62f, 62g) of the semiconductor chips (1f, 1g) are bonded to the positive electrode area (92) of the semiconductor chip (1e). In this way, even when semiconductor chips are disposed in multiple layers on a substrate, the semiconductor chips (1f, 1g) that do not directly contact the substrate can obtain power from the substrate via the semiconductor chip (1e) that directly contacts the substrate. Further, since the semiconductor chips (1e, 1f, 1g) are adjacent to each other, they can communicate with each other through the communication units 40 configured with coils 70 and the like. Therefore, it becomes unnecessary to make some semiconductor chips directly contact the substrate, and the degree of freedom in arrangement of semiconductor chips when manufacturing information processing devices with multiple semiconductor chips is improved.

### Implementation Example 6

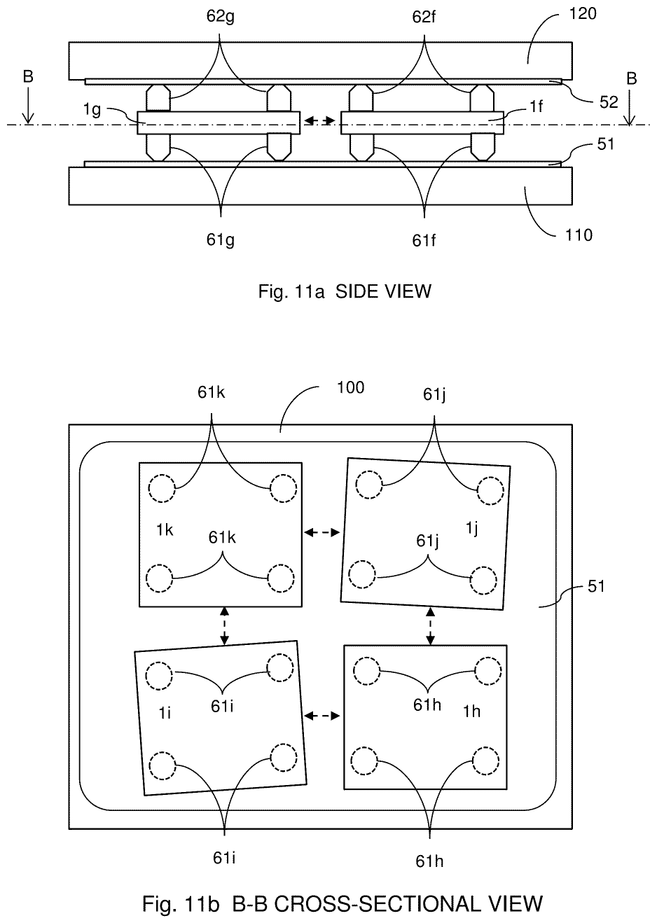

FIG. 11a and FIG. 11b are diagrams showing a sixth implementation example of mounting the semiconductor chip 1 according to this embodiment on a substrate 100. FIG. 11a shows a side view, and FIG. 11b shows a B-B cross-sectional view. As shown in FIG. 11a and FIG. 11b, semiconductor chips (1h, 1i, 1j, 1k) are provided at positions sandwiched by a plurality of substrates (100a, 100b) from both sides. A negative electrode side power supply area (51) is provided on the upper surface (surface on the semiconductor chip 1 side) of the lower substrate 100a. On the other hand, a positive electrode side power supply area (52) is provided on the lower surface (surface on the semiconductor chip 1 side) of the upper substrate 100b. Further, the semiconductor chips (1h, 1i, 1j, 1k) disposed between the substrate 100a and the substrate 100b each comprise a negative electrode side power terminal (61) on one side and a positive electrode side power terminal (62) on the other side.

The semiconductor chips (1h, 1i, 1j, 1k) can receive power supply from each substrate (100a, 100b) by being sandwiched between the two substrates (100a, 100b) in a state where the negative electrode side power terminals (61) contact the power supply area (51) of the substrate 100a and the positive electrode side power terminals (62) contact the power supply area (52) of the substrate 100b. Further, since the negative electrode side power supply area (51) is provided on the substrate 100a and the positive electrode side power supply area (52) is provided on the substrate 100b respectively, there is no need to provide two power supply areas for positive electrode and negative electrode on one substrate, and there is no need to provide intervals between the power supply areas (51, 52), so the power supply areas (51, 52) can be provided on substantially the entire surface of the substrates (100a, 100b).

Therefore, regardless of which position on the substrates (100a, 100b) the semiconductor chip 1 is disposed, the power terminals (61, 62) and the power supply areas (51, 52) contact each other, so there is no need to dispose the semiconductor chip 1 at predetermined positions with high accuracy during manufacturing.

Further, when the substrates (100a, 100b) are configured with soft materials, there is a possibility that the contact positions of the power supply areas (51, 52) of the substrates (100a, 100b) and the power terminals (61, 62) of the semiconductor chip 1 may shift due to curved deformation of the substrates (100a, 100b), but even in such cases, since the power supply areas (51, 52) are configured widely on the surfaces of the substrates (100a, 100b), the semiconductor chip 1 can continue to contact the power supply areas (51, 52) and can continuously obtain power supply.

### Implementation Example 7

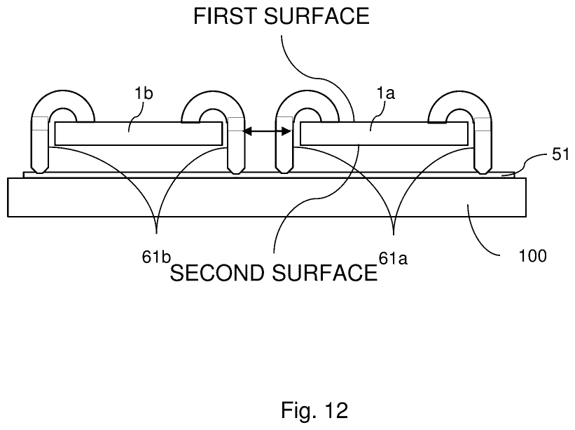

FIG. 12 is a diagram showing a seventh implementation example of mounting the semiconductor chip 1 according to this embodiment on a substrate 100. In each implementation example shown in FIGS. 5a-9, examples were described where power terminals (61, 62) are provided on the first surface (one side) of the semiconductor chip 1 and contact the substrate 100 on this first surface side, but as shown in FIG. 12, the power terminals (61, 62) may be configured to extend through the side surface of the semiconductor chip 1 from the first surface to the second surface side of the semiconductor chip 1 and be connected to the substrate 100 positioned on the second surface side of the semiconductor chip 1.

### Implementation Example 8

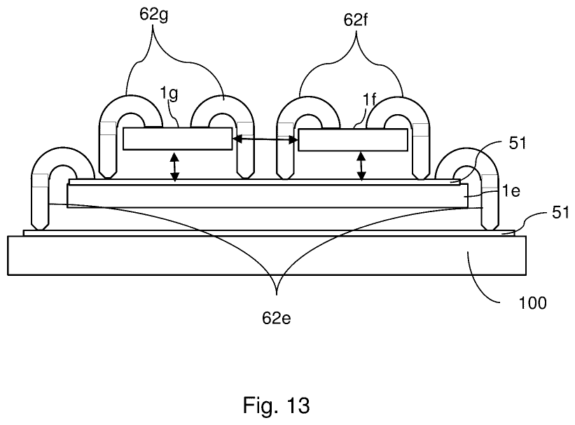

FIG. 13 is a diagram showing an eighth implementation example of mounting the semiconductor chip 1 according to this embodiment on a substrate 100. In the implementation example shown in FIG. 10a to FIG. 10c, an example was described where power terminals (61, 62) are provided on the first surface (one side) of the semiconductor chip (1e) and positive electrode area and negative electrode area are provided on the second surface (other side), but as shown in FIG. 13, power terminals (61, 62) and a positive electrode power supply area (52) and a negative electrode power supply area (51) may be provided on the first surface (one side) of the semiconductor chip (1e), with the power terminals (61, 62) configured to extend through the side surface of the semiconductor chip 1 from the first surface to the second surface side of the semiconductor chip 1 and be connected to the substrate 100 or other semiconductor chips positioned on the second surface side of the semiconductor chip 1.

### Manufacturing Method

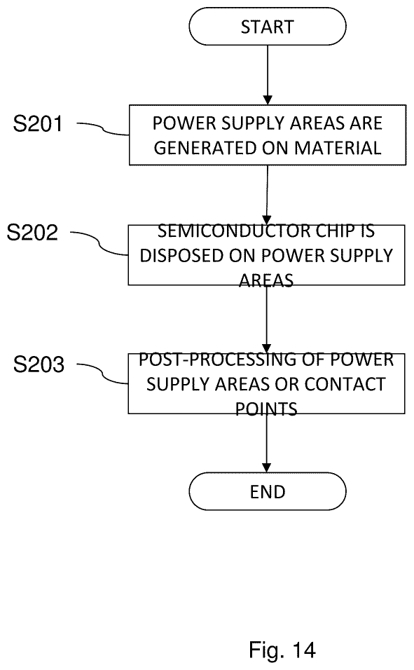

FIG. 14 is a flowchart showing the manufacturing process of a semiconductor chip module according to this embodiment. As a manufacturing process of the semiconductor chip module, first, power supply areas (51, 52) having exposed electrodes are generated on the substrate 100 (step 201). The power supply areas (51, 52) generated on the surface of the substrate 100 in this step (process) may be generated, for example, by applying conductive paint, or may be generated by attaching a conductive adhesive sheet to the substrate 100. Alternatively, they may be generated by attaching conductive film materials such as metal films to the surface of the material.

As the next process, the semiconductor chip 1 is disposed on the power supply areas (51, 52) (step 202). In this step (process), the semiconductor chip 1 is disposed at a position where the positive electrode power terminal (62) of the semiconductor chip 1 contacts the positive electrode power supply area (52) and the negative electrode power terminal (61) contacts the negative electrode power supply area (51). Here, when the power supply areas (51, 52) are generated by applying conductive paint in step 201, the power supply areas (51, 52) and the power terminals (61, 62) can be bonded by bringing the positive electrode power terminal 62 and the negative electrode power terminal 61 into contact with the paint before the paint dries or hardens. Alternatively, when generated by attaching a conductive adhesive sheet to the substrate 100 in step 201, the power supply areas (51, 52) and the power terminals (61, 62) can be bonded by bringing the positive electrode power terminal 62 and the negative electrode power terminal 61 into contact with the adhesive sheet while the adhesive property of the adhesive sheet is maintained. Note that since the area of at least one of the positive electrode power supply area 52 and the negative electrode power supply area 51 is generated to be larger than the area of at least one terminal end of the positive electrode power terminal 62 and the negative electrode power terminal 62, there is no need to increase the positioning accuracy of the semiconductor chip 1 arrangement in this process.

As the next process, post-processing of the power supply areas (51, 52) or contact points is performed (step 203). Here, when the power supply areas (51, 52) are generated by applying conductive paint in step 201, it is desirable to harden or dry the paint to make it difficult for impurities to bond in order to suppress defects where impurities bond between the positive electrode power supply area (52) and the negative electrode power supply area (51) to form short circuits. Specifically, the paint is hardened or dried by sending air with a fan for drying, heating, or irradiating light such as ultraviolet rays.

Alternatively, even when the power supply areas (51, 52) are generated by attaching a conductive adhesive sheet to the substrate in step 201, it is desirable to reduce the adhesive force of the adhesive sheet to make it difficult for impurities to bond in order to suppress defects where impurities bond between the positive electrode power supply area (52) and the negative electrode power supply area (51) to form short circuits. Specifically, the adhesive force of the adhesive sheet is reduced by sending air with a fan, heating, or irradiating light such as ultraviolet rays.

In the above-described implementation examples 1-8, examples were shown where the area of at least one of the positive electrode power supply area 52 and the negative electrode power supply area 51 is generated to be larger than the area of at least one terminal end of the positive electrode power terminal 62 and the negative electrode power terminal 61. With this configuration, in the process of connecting the substrate 100 and the semiconductor chip 1, even with poor positioning accuracy in the long side direction of each power supply area (51, 52), connection between the power supply areas (51, 52) and the power terminals (61, 62) can be achieved, and it is sufficient that adjacent semiconductor chips 1 are disposed within a distance range where they can communicate with each other. Further, in the above-described implementation examples 1-8, examples were shown where the distance (400) between the positive electrode power supply area 52 and the negative electrode power supply area 51 provided on the substrate 100 is shorter than the distance (200) between the positive electrode power terminal 62 and the negative electrode power terminal 61 of the semiconductor chips (1a, 1b), but with this configuration, the degree of freedom in the arrangement position of the semiconductor chip 1 is improved.

Further, in the above-described implementation examples 1-8, examples were shown where power supply areas (areas where electrodes are exposed) are provided on the surfaces of the substrate 100 or the semiconductor chip 1, but in order to prevent the negative electrode and positive electrode power supply areas (51, 52) from temporarily or permanently short-circuiting due to contamination by foreign matter, the semiconductor chip module configured with the substrate 100 and the semiconductor chip 1 after bonding the semiconductor chip 1 may be sealed (molded) with resin.

In each of the above-described implementation examples 1-8, the substrate 100 can apply hard materials with low flexibility like conventional semiconductor substrates, but can also apply soft materials with high flexibility like flexible substrates or cloth. Further, in each implementation example, examples were shown where a plurality of semiconductor chips 1 are bonded to a common substrate 100, but the substrate 100 bonded to the plurality of semiconductor chips 1 does not necessarily need to be a plate-shaped material, and any material having power supply areas (51, 52) on its surface can be applied as the substrate 100.

### Continuous Conveying Implementation

Hereinafter, a manufacturing method for manufacturing a semiconductor module by disposing the above-described semiconductor chips (1a, 1b) on a tape-shaped substrate 100 (tape 71) by a continuous conveying method will be described.

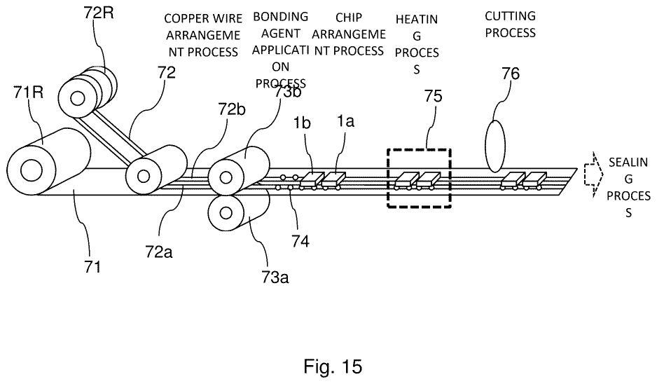

FIG. 15 is a diagram explaining a manufacturing method of a semiconductor module by a continuous conveying method. As shown in FIG. 15, an unwinding roll 71R that supplies tape 71 and unwinding rolls 72R that supply two copper wires 72 are prepared. The two copper wires 72 constitute a positive electrode power line 72b and a negative electrode power line 72a respectively. The positive electrode power line 72b and the negative electrode power line 72a have widths and correspond to the above-described positive electrode power supply area 52 and negative electrode power supply area 51.

The positive electrode power line 72b and the negative electrode power line 72a are attached onto the tape 71 supplied from the unwinding roll 71R (copper wire arrangement process). The tape 71 can be an adhesive tape. For the adhesive tape, for example, a polyimide tape can be used. For the adhesive applied to the adhesive surface of the tape 71, for example, an acrylic adhesive can be used. By placing the copper wire 72 on the adhesive surface of the tape 71, the copper wire 72 is fixed on the tape 71. The copper wire 72 can be urged against the tape 71 by two rollers 73a and 73b. By disposing the copper wire 72 on the adhesive tape 71 in this way, processes such as etching that were conventionally required when disposing power lines can be omitted. Note that instead of the adhesive tape 71 and conductor wire 72, it is also possible to convey tape with metal foil and form electrode structures by etching or the like. In such cases, formation of power lines with complex shapes is also possible.

The widths (lengths in the short direction) of the positive electrode power line 72b and the negative electrode power line 72a can be made longer than the diameter of at least one terminal end of the positive electrode power terminal 62 and the negative electrode power terminal 61 of the semiconductor chip 1. The positive electrode power line 72b and the negative electrode power line 72a are attached and disposed spaced apart from each other in parallel. The separation distance between the positive electrode power line 72b and the negative electrode power line 72a is shorter than the distance between the positive electrode power terminal 62 and the negative electrode power terminal 61 of the semiconductor chip 1.

Note that the unwinding roll 72R may supply enamel wire having an insulating coating instead of copper wire 72. In this case, a process for removing part of the coating on the surface of the enamel wire can be provided before the copper wire arrangement process.

A bonding agent 74 such as solder paste or silver paste is applied to the surfaces of the copper wire 72 (positive electrode power line 72b and negative electrode power line 72a) on the tape 71 by, for example, gravure printing (bonding agent application process).

Note that the copper wire 72 can be a rectangular wire having a substantially rectangular cross-section, and a metal thin film having a composition different from the copper wire 72 may be formed on the surfaces of the copper wire 72 (positive electrode power line 72b and negative electrode power line 72a) (for example, solder plating). In this case, the bonding agent application process can be omitted.

The semiconductor chip 1 is disposed so that the positive electrode power terminal 62 of the semiconductor chip 1 connects to the positive electrode power line 72b and the negative electrode power terminal 61 of the semiconductor chip 1 connects to the negative electrode power line 72a (chip arrangement process). Here, the semiconductor chip 1 is disposed so that the positive electrode power terminal 62 and the negative electrode power terminal 61 contact the bonding agent 74. In this embodiment, two semiconductor chips (1a, 1b) are disposed on the tape 71 spaced apart by a distance enabling communication by inductive coupling with each other.

Next, the semiconductor chip 1 is fixed. In the example of FIG. 15, the semiconductor chip 1 is fixed on the tape 71 by heating the mounting portion of the semiconductor chip 1 (heating process). In the heating process, for example, solder bonding by a reflow furnace 75 can be performed. In the reflow furnace 75, by using low melting point solder, reflow bonding can be performed by low temperature bonding at 150° C. or below.

When the semiconductor chip 1 is fixed, the tape 71 on which the semiconductor chip 1 is fixed can be cut (cutting process). For example, the tape 71 can be cut by a cutter 76.

Each cut tape 71 has a positive electrode power line 72b and a negative electrode power line 72a provided on the upper surface, and the semiconductor chip 1 having the positive electrode power terminal 62 and the negative electrode power terminal 61 bonded thereon by the bonding agent 74 is disposed. A process for sealing the cut tape 71 (on which the semiconductor chip 1 is fixed) can be provided.

Note that underfill sealing may be performed after reflow bonding.

As described above, a semiconductor module comprising the tape 71 on which the semiconductor chip 1 is disposed can be manufactured. The tape 71 of the semiconductor module comprises an adhesive layer having adhesive properties. The positive electrode power line 72b and the negative electrode power line 72a are attached to the surface of the adhesive layer. The semiconductor chips 1 (1a, 1b) comprise coils 70 for performing wireless communication with other semiconductor chips 1 (1b, la), positive electrode power terminals 62 electrically connected to the positive electrode power supply line 72b, and negative electrode power terminals 61 electrically connected to the negative electrode power supply line 72a. The terminals of the semiconductor chip 1 consist of only the positive electrode power terminal 62 and the negative electrode power terminal 61, and communication with other semiconductor chips 1 is performed by wireless communication via inductive coupling through the coil 70. The positive electrode power line 72b and the negative electrode power line 72a are attached and disposed parallel to each other.

### Bending Process

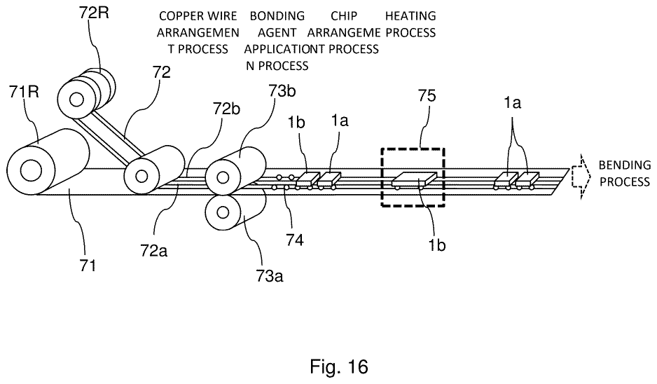

A bending process for bending the tape 71 may be provided after the above-described chip arrangement process. FIG. 16 is a diagram explaining a manufacturing method of a semiconductor module by a continuous conveying method when providing a bending process.

As described above, a positive electrode power supply area (positive electrode power line 72b) having an exposed positive electrode and a negative electrode power supply area (negative electrode power line 72a) having an exposed negative electrode are disposed on the tape 71, one or more semiconductor chips 1a are disposed on the adhesive surface of the tape 71, and subsequently, one or more semiconductor chips 1b are disposed on the adhesive surface of the tape 71. The semiconductor chips 1a and 1b comprise, as described above, coils 70, positive electrode power terminals 62 electrically connected to the positive electrode power line 72b, and negative electrode power terminals 61 electrically connected to the negative electrode power line 72a.

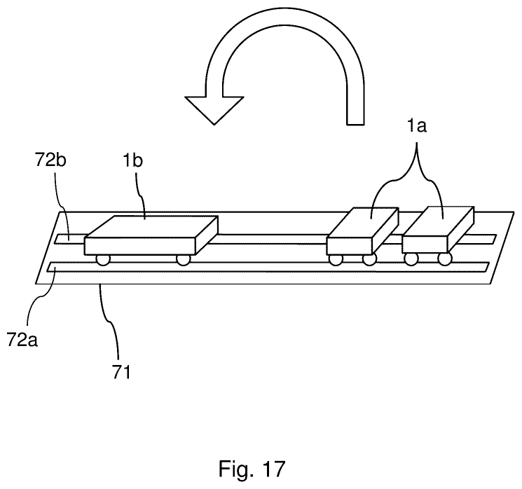

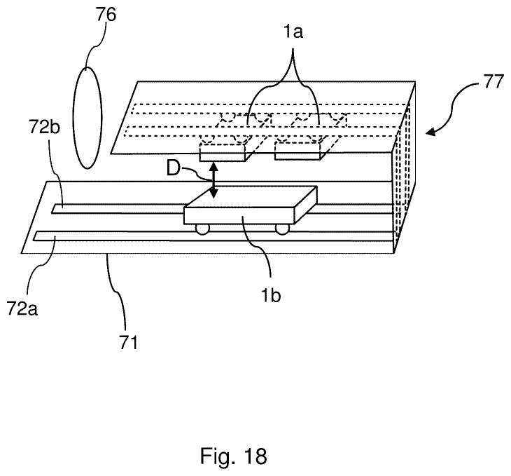

After the heating process, as shown in FIG. 17, the tape 71 is bent between one or more preceding semiconductor chips 1a and one or more subsequent semiconductor chips 1b. FIG. 18 is a diagram explaining the bent structure of a semiconductor module. As shown in FIG. 18, after bending, a bent portion 77 is formed so that the upper surface of the semiconductor chip 1b (open surface opposite to the surface fixed to the tape 71) and the upper surface of the semiconductor chip la (open surface opposite to the surface fixed to the tape 71) face each other. In other words, the tape 71 is bent so that at least part of the adhesive surface of the tape 71 on which the semiconductor chips 1b and la are disposed faces each other.

The open surface of the semiconductor chip 1b and the open surface of the semiconductor chip la are separated by a distance D. The distance D is set to a distance at which inductive coupling occurs between the coils 70 provided in the semiconductor chips 1a and 1b. That is, the tape 71 is bent with spacing to enable wireless communication by inductive coupling between the semiconductor chips 1a and 1b.

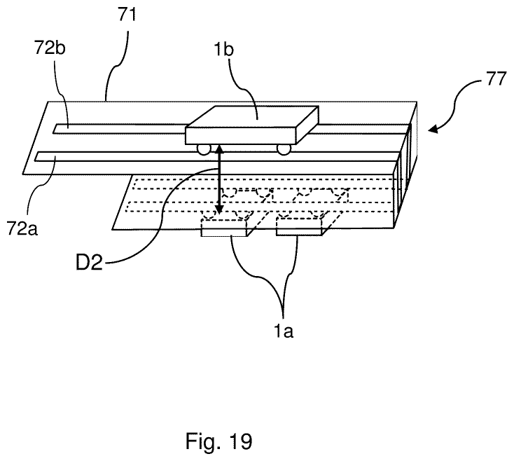

Note that the tape 71 may be bent in the opposite direction from FIG. 17. FIG. 19 is a diagram explaining a bent structure in which the tape 71 is bent so that the surface opposite to the adhesive surface of the tape 71 (back surface) faces each other. In the semiconductor module after bending shown in FIG. 19, the back surfaces at positions of the tape 71 where the semiconductor chips 1 are disposed face each other. The semiconductor chips 1a and 1b are disposed on the adhesive surface, and the back surface portion on the back side of the portion where the semiconductor chip la is disposed on the adhesive surface and the back surface portion on the back side of the portion where the semiconductor chip 1b is disposed on the adhesive surface face each other. The semiconductor chip la and the semiconductor chip 1b are bent to be separated by a distance D2. The material of the tape 71 is selected so that inductive coupling occurs between the coils 70 of the semiconductor chips 1a and 1b even with the tape 71 interposed.

After the bending process, a cutting process can be provided to cut the tape 71 so as to separate the semiconductor module including the opposing semiconductor chips 1a and 1b. In the example of FIG. 18, the tape 71 can be cut with the cutter 76 between the semiconductor chip 1b and the subsequent semiconductor chip 1.

After the cutting process, a sealing process for collectively sealing the cut semiconductor modules can be provided.

As described above, a semiconductor module comprising semiconductor chips (1a, 1b) and the tape 71 (substrate) on which the semiconductor chips (1a, 1b) are mounted can be manufactured. In the semiconductor module manufactured as described above, the tape 71 comprises a positive electrode power supply area (positive electrode power line 72b) having an exposed positive electrode and a negative electrode power supply area (negative electrode power line 72a) having an exposed negative electrode. The semiconductor chips (1a, 1b) comprise coils 70 for performing wireless communication with the other semiconductor chips (1b, la), positive electrode power terminals 62 electrically connected to the positive electrode power supply areas, and negative electrode power terminals 61 electrically connected to the negative electrode power supply areas. The tape 71 has an adhesive surface (first main surface) and a back surface (second main surface). The semiconductor module comprises a bent structure configured so that the adhesive surface and at least part of the adhesive surface face each other. Note that the bent structure may be configured so that the back surface of the tape 71 and at least part of the back surface face each other.

The bent structure of the semiconductor module can be configured so that the mounting surfaces of the semiconductor chips (1a, 1b) face each other.

The terminals of the semiconductor chip 1 consist of only the positive electrode power terminal 62 and the negative electrode power terminal 61, and communication between the semiconductor chip 1 and other semiconductor chips 1 is performed by wireless communication via the coil 70.

The distance between the positive electrode power supply area (positive electrode power line 72b) and the negative electrode power supply area (negative electrode power line 72a) provided on the tape 71 is shorter than the distance (pitch) between the positive electrode power terminal 62 and the negative electrode power terminal 61 of the semiconductor chip 1.

### Arrangement of Magnetic Material

As described above, in the semiconductor module according to this embodiment, communication by inductive coupling is performed between the two semiconductor chips 1a and 1b, and by disposing a magnetic material on a closed magnetic circuit relating to the inductive coupling, communication efficiency can be increased. The arrangement of the magnetic material is described below.

### Disposing Magnetic Material Between Horizontal Coils

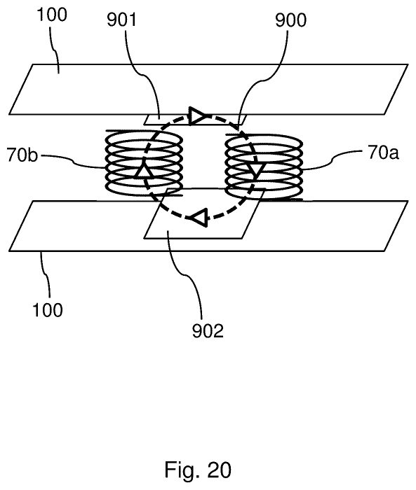

The two semiconductor chips 1a and 1b can be disposed spaced apart in a horizontal direction (direction perpendicular to the axial direction of the coil 70), and a magnetic material can be disposed on a closed magnetic circuit relating to inductive coupling generated between the two semiconductor chips 1a and 1b. FIG. 20 is a diagram showing an arrangement example of magnetic materials. FIG. 20 shows coils 70a and 70b provided in the two semiconductor chips 1a and 1b. In the example of FIG. 20, magnetic materials 901 and 902 are disposed on the mounting surface side of substrate 100 (which may be tape 71; the same applies hereinafter) on which semiconductor chips 1a and 2b are mounted. A closed magnetic circuit 900 relating to inductive coupling generated between the two coils 70a and 70b is formed so as to pass through the magnetic materials 901 and 902. Only either one of the magnetic materials 901 and 902 may be disposed. Further, at least either of the magnetic materials 901 and 902 may be disposed on a surface opposite to the surface on which the semiconductor chips 1a and 2b are mounted of the substrate 100.

### Magnetic Sheet

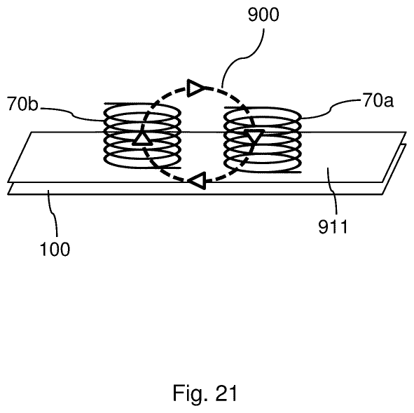

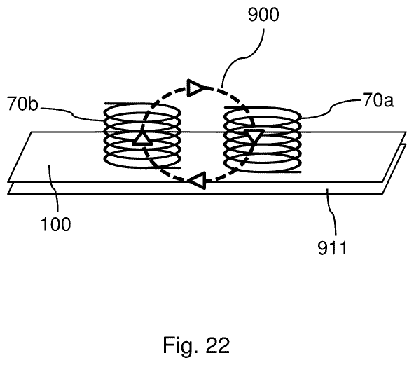

At least either of the magnetic materials 901 and 902 may be a sheet-shaped magnetic material. FIG. 21 is a diagram showing an arrangement example of a sheet-shaped magnetic material 911. As shown in FIG. 21, a sheet-shaped magnetic material sheet 911 is disposed on the mounting surface side of substrate 100 on which semiconductor chips 1a and 1b are mounted. For example, when substrate 100 is a tape, the magnetic material sheet 911 can be attached to the tape, and semiconductor chips 1a and 1b can be disposed spaced apart on the magnetic material sheet 911. In this case as well, a closed magnetic circuit 900 relating to inductive coupling generated between the two coils 70a and 70b is formed so as to pass through the magnetic material sheet 911. The magnetic material sheet 911 may be disposed on a surface (back surface) opposite to the surface on which the semiconductor chips 1a and 1b are mounted of the substrate 100. FIG. 22 is a diagram showing an example of disposing the magnetic material sheet 911 on the back surface of substrate 100.

### Lamination Processing

The magnetic material (901, 902, 911) can be fixed to one surface of substrate 100 by lamination processing. Alternatively, the magnetic material (901, 902, 911) can also be fixed to one surface of substrate 100 by applying a coating liquid containing a magnetic material to the tape.

### Substrate of Magnetic Sheet

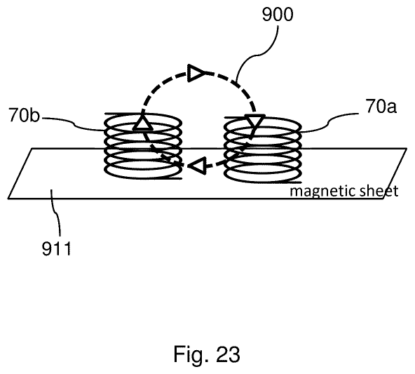

The substrate 100 may be formed by a magnetic material. FIG. 23 is a diagram showing a case where substrate 100 is made a magnetic material sheet 911. In the example of FIG. 23, semiconductor chips 1a and 1b are mounted on a substrate (magnetic material sheet 911) formed by a magnetic material. In this case as well, a closed magnetic circuit 900 relating to inductive coupling generated between the two coils 70a and 70b is formed so as to pass through the magnetic material sheet 911.

### Selective Arrangement of Magnetic Material

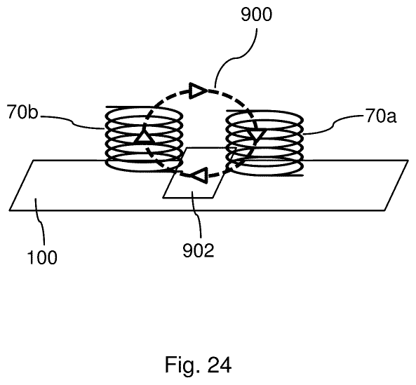

The magnetic materials 901 and 902 can be disposed on only part of substrate 100. FIG. 24 is a diagram showing an example of disposing magnetic material 902 in a gap between semiconductor chips 1a and 1b. As shown in FIG. 24, the magnetic material 902 can be disposed only in the gap between semiconductor chips 1a and 1b on one surface (the mounting surface in the example of FIG. 24) of substrate 100. When sandwiching semiconductor chips 1a and 1b between two substrates 100 (as in the case shown in FIG. 20), when disposing two magnetic materials (901, 902), at least one of the two magnetic materials (901, 902) can be disposed only in the gap between semiconductor chips 1a and 1b. By performing selective arrangement of magnetic materials, it is possible to further improve communication efficiency. Particularly when improving communication efficiency in the horizontal direction, it is preferable to dispose magnetic materials 901 and 902 only in the gap between semiconductor chips 1a and 1b as shown in FIG. 24.

### Power Supply Area

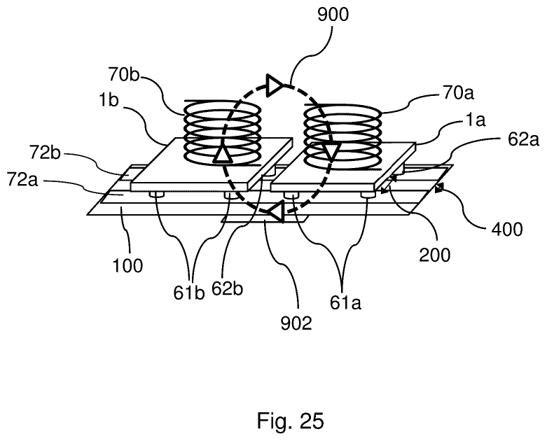

FIG. 25 is a diagram showing a mounting example of semiconductor chips 1a and 1b. On substrate 100 on which semiconductor chips 1a and 1b are mounted, a positive electrode power supply area (positive electrode power line 72b) having an exposed positive electrode and a negative electrode power supply area (negative electrode power line 72a) having an exposed negative electrode can be provided. Semiconductor chips 1a and 1b can comprise a positive electrode power terminal (not shown) connected to the positive electrode power supply area (positive electrode power line 72b) and a negative electrode power terminal (not shown) connected to the negative electrode power supply area (negative electrode power line 72a). As described above, a distance between the positive electrode power supply area (positive electrode power line 72b) and the negative electrode power supply area (negative electrode power line 72a) provided on substrate 100 can be shorter than a distance between the positive electrode power terminal 62 and the negative electrode power terminal 61. In the example of FIG. 25, two copper wires 72 (positive electrode power line 72b and negative electrode power line 72a) are attached on tape 71 (substrate 100), and a distance (400) between positive electrode power line 72b and negative electrode power line 72a is shorter than a distance (200) between positive electrode power terminal 62 and negative electrode power terminal 61.

### Magnetic Material Between Vertical Coils

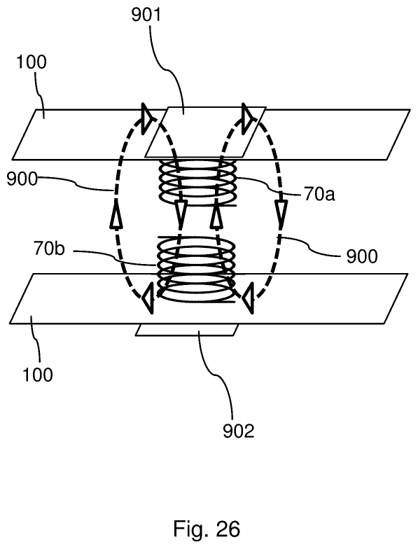

As shown in FIG. 26, semiconductor chips 1a and 1b can also be stacked spaced apart in a vertical direction (axial direction of coil 70, thickness direction of semiconductor chip 1). Semiconductor chips 1a and 1b have opposing surfaces that face each other and opposite surfaces opposite to the opposing surfaces. Magnetic materials 901 and 902 are disposed in proximity to the respective opposite surfaces of semiconductor chips 1a and 1b. In the example of FIG. 26, magnetic materials 901 and 902 are disposed on a back surface opposite to the mounting surface of semiconductor chip 1 of substrate 100. A magnetic material (901 or 902) may be disposed in proximity to the opposite surface of only either one of semiconductor chips 1a and 1b.

### Bending Processing

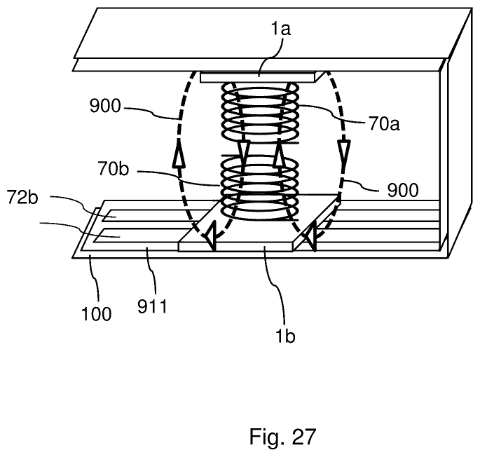

FIG. 27 is a diagram explaining forming a configuration (semiconductor module) in which the above two semiconductor chips 1a and 1b are stacked in the vertical direction by bending processing. A magnetic material sheet 911 can be attached to one surface of substrate 100 (for example, tape 71), semiconductor chips 1a and 1b can be disposed on the magnetic material sheet 911, and substrate 100 can be bent together with the magnetic material sheet 911 between semiconductor chip la and semiconductor chip 1b so that the respective open surfaces of semiconductor chips 1a and 1b face each other.

Also for the semiconductor module shown in FIG. 27, substrate 100 can be provided with a positive electrode power supply area (positive electrode power line 72b) having an exposed positive electrode and a negative electrode power supply area (negative electrode power line 72a) having an exposed negative electrode. Positive electrode power line 72b and negative electrode power line 72a can be disposed on magnetic material sheet 911. Semiconductor chips 1a and 1b comprise a positive electrode power terminal 62 (not shown) connected to the positive electrode power supply area (positive electrode power line 72b) and a negative electrode power terminal 61 (not shown) connected to the negative electrode power supply area (negative electrode power line 72a), and a distance between the positive electrode power supply area 52 and the negative electrode power supply area 51 provided on substrate 100 can be shorter than a distance between the positive electrode power terminal 62 and the negative electrode power terminal 61.

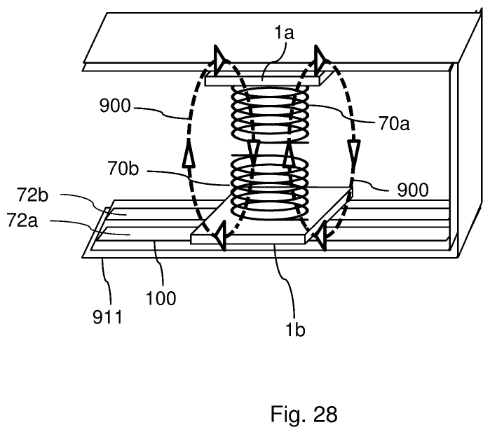

FIG. 28 is a diagram showing another example of stacking semiconductor chips 1a and 1b by bending processing. In the example of FIG. 28, magnetic material sheet 911 is attached to a surface opposite to the mounting surface of semiconductor chip 1 of substrate 100.

Also in the example of FIG. 28, substrate 100 can be provided with a positive electrode power supply area (positive electrode power line 72b) having an exposed positive electrode and a negative electrode power supply area (negative electrode power line 72a) having an exposed negative electrode.

Semiconductor chips 1a and 1b comprise a positive electrode power terminal 62 (not shown) connected to the positive electrode power supply area (positive electrode power line 72b) and a negative electrode power terminal 61 (not shown) connected to the negative electrode power supply area (negative electrode power line 72a), and a distance between the positive electrode power supply area 52 and the negative electrode power supply area 51 provided on substrate 100 can be shorter than a distance between the positive electrode power terminal 62 and the negative electrode power terminal 61.

### Lamination Processing

Magnetic materials (901, 902, 911) can be fixed to substrate 100 by lamination processing. Also, semiconductor chip 1 can be fixed to substrate 100 by lamination processing. Alternatively, magnetic materials (901, 902, 911) can also be fixed to one surface of substrate 100 by applying a coating liquid containing a magnetic material to the tape.

### Manufacturing Method

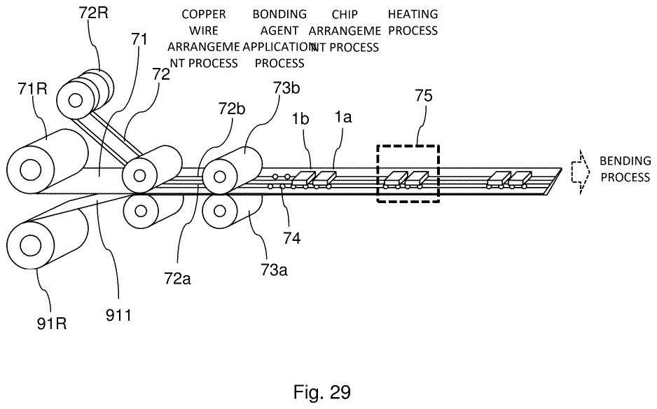

FIG. 29 is a diagram explaining a method of manufacturing a semiconductor module together with magnetic material sheet 911 by a continuous conveying method. As shown in the figure, an unwinding roll 91R supplies magnetic material sheet 911. Copper wire 72 can be pressed against one surface of tape 71 by two rollers 73a and 73b, and magnetic material sheet 911 can be pressed against the other surface of tape 71. As described above, by bending substrate 100 together with magnetic material sheet 911 between semiconductor chip la and semiconductor chip 1b, a semiconductor module can be formed so that semiconductor chips 1a and 1b face each other in the vertical direction.

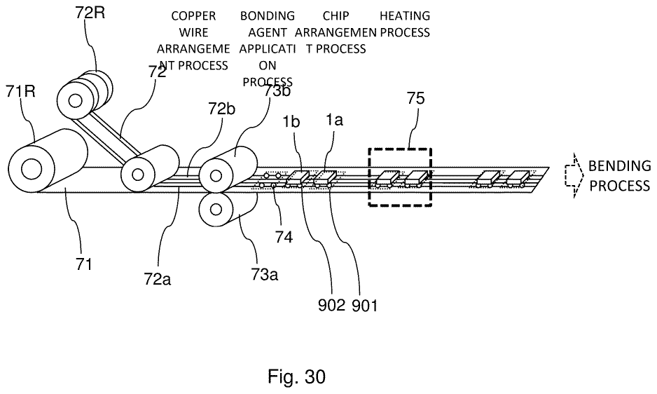

FIG. 30 is a diagram explaining another example of manufacturing a semiconductor module together with magnetic materials (901, 902) by a continuous conveying method. Without using magnetic material sheet 911, magnetic materials (901, 902) can be disposed at selective positions of tape 71. In the example of FIG. 30, before the bonding agent application process, magnetic materials (901, 902) are attached to the back surface (the surface on which copper wire 72 is attached, that is, the surface opposite to the surface on which semiconductor chip 1 is mounted). For example, adhesive layers can be provided on both surfaces of tape 71, and magnetic materials (901, 902) can be attached by pressing. Also, as described above, magnetic materials (901, 902) may be fixed by lamination processing. A process of disposing magnetic materials (901, 902) may be provided after the bonding agent application process. Magnetic materials (901, 902) can be disposed on the back surface of tape 71 so as to be aligned with the application positions of four bonding agents, and positive electrode power terminal 62 and negative electrode power terminal 61 of semiconductor chip 1 are brought into contact with these four bonding agents.

### Power Supply Area

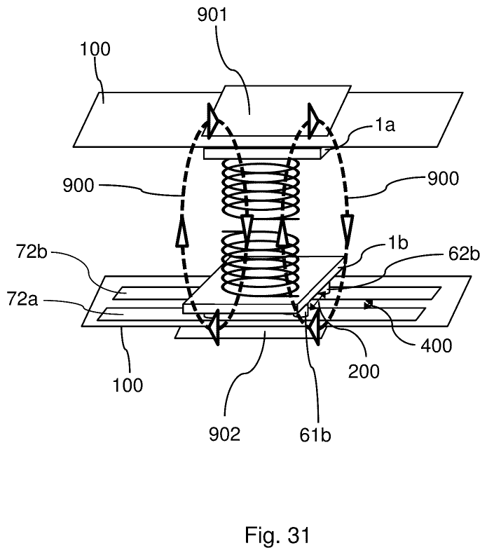

FIG. 31 is a diagram explaining a semiconductor module in which semiconductor chips 1a and 1b are stacked spaced apart in the vertical direction. Here as well, a positive electrode power supply area (positive electrode power line 72b) having an exposed positive electrode and a negative electrode power supply area (negative electrode power line 72a) having an exposed negative electrode can be provided on substrate 100 on which semiconductor chips 1a and 1b are mounted, and semiconductor chips 1a and 1b can comprise a positive electrode power terminal 62 (not shown) connected to the positive electrode power supply area (positive electrode power line 72b) and a negative electrode power terminal 61 (not shown) connected to the negative electrode power supply area (negative electrode power line 72a). As described above, a distance between the positive electrode power supply area (positive electrode power line 72b) and the negative electrode power supply area (negative electrode power line 72a) provided on substrate 100 can be shorter than a distance between the positive electrode power terminal 62 and the negative electrode power terminal 61. Also in the example of FIG. 31, two copper wires 72 (positive electrode power line 72b and negative electrode power line 72a) are attached on tape 71 (substrate 100), and a distance (400) between positive electrode power line 72b and negative electrode power line 72a is shorter than a distance (200) between positive electrode power terminal 62 and negative electrode power terminal 61.

### Disposing Magnetic Material Between Vertical Coils

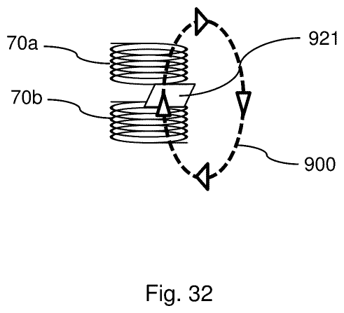

In the above-described stacking configuration in the vertical direction, magnetic materials (901, 902) are disposed on one surface of substrate 100, but a magnetic material may be disposed on a closed magnetic circuit between opposing surfaces of the two semiconductor chips 1a and 1b (that is, between the two coils 70). FIG. 32 is a diagram showing an example of disposing a magnetic material between coils. As shown in the figure, the two semiconductor chips 1a and 1b are disposed spaced apart in the vertical direction (axial direction of coil 70), and a magnetic material 921 is disposed in a gap between the spaced semiconductor chips 1a and 1b (between coils 70a and 70b). The magnetic material 921 is disposed on a closed magnetic circuit 900 relating to inductive coupling generated between coils 70a and 70b.

### A Plurality of Magnetic Materials

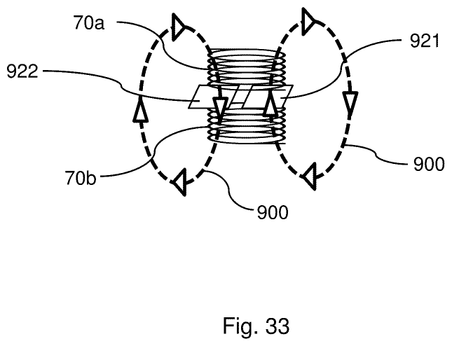

A plurality of magnetic materials 921 can be disposed in a same semiconductor module. FIG. 33 is a diagram showing an example of disposing a plurality of magnetic materials (921, 922). A plurality of magnetic materials (921, 922) are disposed in a gap between the spaced semiconductor chips 1a and 1b (between coils 70a and 70b), and all magnetic materials (921, 922) are disposed on closed magnetic circuit 900. The magnetic materials (921, 922) may be disposed in two or more.

### Bending Processing

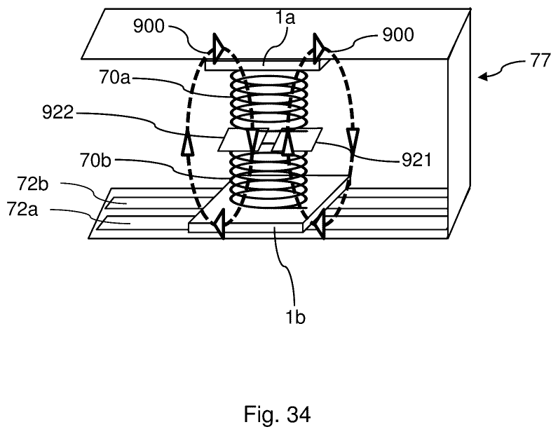

Even when disposing magnetic materials (921, 922) between semiconductor chips 1a and 1b stacked in the vertical direction, the semiconductor module can be manufactured by bending processing. FIG. 34 is a diagram showing an example of forming a semiconductor module by bending processing. Semiconductor chips 1a and 1b can be disposed on one surface of a same substrate 100 (for example, tape 71), and a semiconductor module can be formed by bending substrate 100 between semiconductor chips 1a and 1b so that semiconductor chips 1a and 1b face each other. As shown in FIG. 34, a bent portion 77 is formed. When bending substrate 100, magnetic materials 921 and 922 are sandwiched between opposing semiconductor chips 1a and 1b.

The magnetic materials (921, 922) can be fixed to semiconductor chip 1 by, for example, lamination processing.

### Magnetic Material Sheet

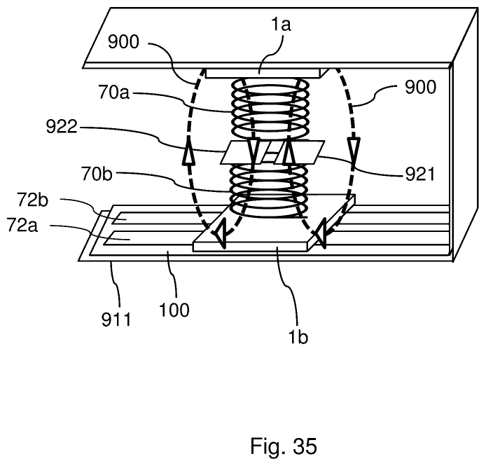

A sheet-shaped magnetic material sheet 911 may be disposed on a surface (back surface) opposite to the mounting surface of semiconductor chip 1 of substrate 100. FIG. 35 is a diagram showing an example of disposing magnetic material sheet 911. As shown in the figure, magnetic material sheet 911 is disposed on the back surface of substrate 100 (for example, tape 71), and substrate 100 is subjected to bending processing together with magnetic material sheet 911.

The magnetic material sheet 911 can be fixed to substrate 100 by lamination processing.

### Power Supply Area

Also for the semiconductor module formed by bending processing shown in FIGS. 34 and 35, similarly to the configuration shown in FIG. 31, substrate 100 can be provided with a positive electrode power supply area (positive electrode power line 72b) having an exposed positive electrode and a negative electrode power supply area (negative electrode power line 72a) having an exposed negative electrode. Also in this case, semiconductor chips 1a and 1b comprise a positive electrode power terminal 62 (not shown) connected to the positive electrode power supply area (positive electrode power line 72b) and a negative electrode power terminal 61 (not shown) connected to the negative electrode power supply area (negative electrode power line 72a), and a distance between the positive electrode power supply area 52 and the negative electrode power supply area 51 provided on substrate 100 can be shorter than a distance between the positive electrode power terminal 62 and the negative electrode power terminal 61.

The present embodiment has been described above, but the above embodiment is for facilitating understanding of the present invention and is not for limiting interpretation of the present invention. The present invention can be changed and improved without departing from the spirit thereof, and the present invention includes equivalents thereof.

1. A semiconductor module comprising:
a first semiconductor chip having a first coil;
a second semiconductor chip having a second coil capable of communication with the first coil via inductive coupling, the second semiconductor chip being disposed spaced apart in a horizontal direction perpendicular to an axial direction of the first coil; and
a magnetic material disposed on a closed magnetic circuit relating to the inductive coupling at least between the first and second semiconductor chips.

2. The semiconductor module according to claim 1, wherein
the first and second semiconductor chips are disposed on a substrate formed by the magnetic material.

3. The semiconductor module according to claim 1, wherein
a sheet-shaped magnetic material is provided on one surface of a substrate on which the first and second semiconductor chips are disposed.

4. The semiconductor module according to claim 3, wherein
the magnetic material is fixed to the one surface of the substrate by lamination processing.

5. The semiconductor module according to claim 1, wherein
the magnetic material is disposed in a gap between the first and second semiconductor chips on one surface of a substrate on which the first and second semiconductor chips are disposed.

6. The semiconductor module according to claim 1, wherein
the first and second semiconductor chips are mounted on a substrate,
the substrate comprises a positive electrode power supply area having an exposed positive electrode and a negative electrode power supply area having an exposed negative electrode,
the first and second semiconductor chips each comprise a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.

7. A semiconductor module comprising:
a first semiconductor chip having a first coil;
a second semiconductor chip having a second coil capable of communication with the first coil via inductive coupling, the second semiconductor chip being disposed spaced apart in an axial direction of the first coil;
opposing surfaces of the first and second semiconductor chips;
respective opposite surfaces spaced apart from the opposing surfaces in the axial direction; and
a magnetic material disposed in proximity to at least one of the respective opposite surfaces.

8. The semiconductor module according to claim 7, wherein
the first and second semiconductor chips are mounted on a first surface of a same substrate,
a sheet-shaped magnetic material is disposed on the first surface of the substrate or on a second surface opposite to the first surface, and
the substrate is folded so that the first and second semiconductor chips face each other.

9. The semiconductor module according to claim 8, wherein
the magnetic material is fixed to the substrate by lamination processing.

10. The semiconductor module according to claim 8, wherein the semiconductor chips are fixed to the substrate by lamination processing.

11. The semiconductor module according to claim 7, wherein
the first and second semiconductor chips are mounted on a substrate,
the substrate comprises a positive electrode power supply area having an exposed positive electrode and a negative electrode power supply area having an exposed negative electrode,
the first semiconductor chip comprises a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.

12. A semiconductor module comprising:
a first semiconductor chip having a first coil;
a second semiconductor chip having a second coil capable of communication with the first coil via inductive coupling, the second semiconductor chip being disposed spaced apart in an axial direction of the first coil; and
a magnetic material disposed on a closed magnetic circuit relating to the inductive coupling between the first and second semiconductor chips.

13. The semiconductor module according to claim 12, wherein
the magnetic material is disposed between opposing surfaces of the first and second semiconductor chips.

14. The semiconductor module according to claim 12, wherein
a plurality of magnetic materials are disposed.

15. The semiconductor module according to claim 12, wherein
the magnetic material is fixed to the first or second semiconductor chip by lamination processing.

16. The semiconductor module according to claim 12, wherein
the first and second semiconductor chips are mounted on a first surface of a same substrate, and
the substrate is folded so that the first and second semiconductor chips face each other.

17. The semiconductor module according to claim 16, wherein
a sheet-shaped magnetic material is disposed on the first surface of the substrate or on a second surface opposite to the first surface.

18. The semiconductor module according to claim 17, wherein
the magnetic material is fixed to the substrate by lamination processing.

19. The semiconductor module according to claim 12, wherein
the first and second semiconductor chips are mounted on a substrate,
the substrate comprises a positive electrode power supply area having an exposed positive electrode and a negative electrode power supply area having an exposed negative electrode,
the first and second semiconductor chips each comprise a positive electrode power terminal connected to the positive electrode power supply area and a negative electrode power terminal connected to the negative electrode power supply area, and
a distance between the positive electrode power supply area and the negative electrode power supply area provided on the substrate is shorter than a distance between the positive electrode power terminal and the negative electrode power terminal.
